(19) United States
(12) Patent Application Publication
(10) Pub. No.: US 2026/0188210 A1
(43) Pub. Date: Jul. 2, 2026

(54) Display Substrate and Driving Method and Preparation Method Therefor, and Display Apparatus

(71) Applicants: Chengdu BOE Optoelectronics Technology Co., Ltd., Chengdu, Sichuan (CN); BOE Technology Group Co., Ltd., Beijing (CN); Beijing BOE Technology Development Co., Ltd., Beijing (CN)

(72) Inventors: Zhu WANG, Beijing (CN); Zhongman ZHAO, Beijing (CN); Ling SHI, Beijing (CN)

(21) Appl. No.: 18/840,509

(22) PCT Filed: Oct. 26, 2023
(86) PCT No.: PCT/CN2023/126746

§ 371 Date: Aug. 22, 2024

(51) Int. Cl. G09G 3/3233; H10K 59/131; H10K 59/60

(52) U.S. Cl. CPC G09G 3/3233; H10K 59/131; H10K 59/60; G09G 2300/0426; G09G 2300/0861; G09G 2310/08

(57) ABSTRACT

A display substrate includes a plurality of circuit units, and at least one circuit unit includes a pixel driving circuit, a sensing circuit and a photosensitive device, wherein the pixel driving circuit includes at least one light emitting control transistor, the sensing circuit at least includes a sensing control transistor, the sensing control transistor is connected to the photosensitive device, the light emitting control transistor and the sensing control transistor are different types of transistors; and in the at least one circuit unit, the light emitting control transistors and the sensing control transistors are connected to the same light emitting signal line.

### CROSS-REFERENCE TO RELATED APPLICATION

This application is a national stage application of PCT Application No. PCT/CN2023/126746, which is filed on Oct. 26, 2023 and entitled “Display Substrate and Driving Method and Preparation Method Therefor, and Display Apparatus”, the content of which should be regarded as being incorporated herein by reference.

### TECHNICAL FIELD

The present disclosure relates to, but is not limited to, the field of display technologies, and particularly to a display substrate, a driving method and a preparation method therefor, and a display apparatus.

### BACKGROUND

An Organic Light Emitting Diode (OLED for short) and a Quantum dot Light Emitting Diode (QLED for short) are active light emitting display devices and have advantages such as self-luminescence, wide viewing angle, high contrast ratio, low power consumption, very high response speed, lightness and thinness, flexibility, and low cost. With continuous development of display technologies, a display apparatus (Display) in which an OLED or a QLED is used as a light emitting device and a Thin Film Transistor (TFT) is used for signal control has become a mainstream product in the field of display at present.

### SUMMARY

The following is a summary of subject matters described herein in detail. This summary is not intended to limit the protection scope of claims.

In one aspect, the present disclosure provides a display substrate, including a plurality of circuit units, and at least one circuit unit includes a pixel driving circuit, a sensing circuit and a photosensitive device; the pixel driving circuit at least includes a driving transistor and at least one light emitting control transistor, wherein a first end of the light emitting control transistor is connected to a first power supply line, a second end of the light emitting control transistor is connected to a first end of the driving transistor, or the first end of the light emitting control transistor is connected to a second end of the driving transistor, and the second end of the light emitting control transistor is connected to a light emitting device; the sensing circuit at least includes a sensing control transistor, wherein a first end of the sensing control transistor is connected with the photosensitive device, a second end of the sensing control transistor is connected to a sensing signal line, and the light emitting control transistor and the sensing control transistor are different types of transistors; and in at least one circuit unit, the light emitting control transistor and the sensing control transistor are connected to the same light emitting signal line, the light emitting signal line is configured to provide a light emitting control signal to the pixel driving circuit.

In an exemplary implementation, the light emitting control transistor is a polysilicon transistor, and the sensing control transistor is an oxide transistor; or the light emitting control transistor is an oxide transistor, and the sensing control transistor is a polysilicon transistor.

In an exemplary implementation, the light emitting control transistor at least includes a light emitting control gate electrode, the sensing control transistor at least includes a sensing control gate electrode, the light emitting control gate electrode is directly connected to the light emitting signal line, and the sensing control gate electrode is connected to the light emitting signal line through a light emitting connection electrode.

In an exemplary implementation, in a direction perpendicular to the display substrate, the display substrate includes a plurality of conductive layers, the light emitting control gate electrode and the light emitting signal line are disposed in the same conductive layer, the sensing control gate electrode and the light emitting signal line are disposed in different conductive layers, and the light emitting connection electrode and the sensing control gate electrode are disposed in different conductive layers.

In an exemplary implementation, the plurality of conductive layers at least include a first conductive layer, a second conductive layer, a third conductive layer and a fourth conductive layer disposed sequentially; the light emitting signal line and the light emitting control gate electrode are disposed in the first conductive layer and are of an integral structure connected to each other; the sensing control gate electrode is respectively disposed in the second conductive layer and the third conductive layer; and the light emitting connection electrode is disposed in the fourth conductive layer, and the light emitting connection electrode is respectively connected with the light emitting signal line and the sensing control gate electrode through a via hole.

In an exemplary implementation, the sensing control gate electrode includes a bottom gate electrode and a top gate electrode, wherein the bottom gate electrode is disposed in the second conductive layer, the top gate electrode is disposed in the third conductive layer, the light emitting connection electrode is respectively connected to the bottom gate electrode and the top gate electrode through a via hole.

In an exemplary implementation, the photosensitive device at least includes a photosensitive first electrode, a photosensitive second electrode, and a photosensitive layer disposed between the photosensitive first electrode and the photosensitive second electrode, wherein the photosensitive first electrode is connected to a sensing power supply line, and the photosensitive second electrode is connected to a first electrode of the sensing control transistor.

In an exemplary implementation, the sensing control transistor at least includes a sensing active layer; in a direction perpendicular to the display substrate, the display substrate at least includes a first semiconductor layer disposed on a base substrate and a second semiconductor layer disposed on a side of the first semiconductor layer away from the base substrate, wherein the photosensitive first electrode, the photosensitive second electrode and the photosensitive layer are disposed in the first semiconductor layer, and the sensing active layer is disposed in the second semiconductor layer.

In an exemplary implementation, the photosensitive first electrode and the photosensitive second electrode are formed by performing a conductorization treatment on the first semiconductor layer, and the photosensitive layer is formed by doping the first semiconductor layer.

In an exemplary implementation, the at least one circuit unit further includes an eleventh connection electrode and a thirty-first connection electrode, the photosensitive first electrode is connected to the sensing power supply line through the eleventh connection electrode and the thirty-first connection electrode.

In an exemplary implementation, in a direction perpendicular to the display substrate, the display substrate includes a plurality of conductive layers, and the eleventh connection electrode, the thirty-first connection electrode and the sensing power supply line are disposed in different conductive layers; the eleventh connection electrode is connected to the photosensitive first electrode through a via hole, the thirty-first connection electrode is connected to the eleventh connection electrode through a via hole, and the sensing power supply line is connected to the thirty-first connection electrode through a via hole.

In an exemplary implementation, the at least one circuit unit further includes a twelfth connection electrode, and the photosensitive second electrode is connected to a first region of the sensing active layer through twelfth connection electrode.

In an exemplary implementation, the twelfth connection electrode is disposed on a side of the sensing active layer away from the base substrate, the twelfth connection electrode is connected to the photosensitive second electrode through a via hole, and the twelfth connection electrode is connected to a first region of the sensing active layer through another via hole.

In an exemplary implementation, the at least one circuit unit further includes a thirteenth connection electrode and a thirty-second connection electrode, and a second region of the sensing active layer is connected to the sensing signal line through the thirteenth connection electrode and the thirty-second connection electrode.

In an exemplary implementation, in a direction perpendicular to the display substrate, the display substrate includes a plurality of conductive layers, and the thirteenth connection electrode, the thirty-second connection electrode and the sensing signal line are disposed in different conductive layers; the thirteenth connection electrode is connected to the second region of the sensing active layer through a via hole, the thirty-second connection electrode is connected to the thirteenth connection electrode through a via hole, and the sensing signal line is connected to the thirty-second connection electrode through a via hole.

In the exemplary implementation, a shape of the sensing power supply line is a straight line shape or a polyline shape in which a main body portion extends along a second direction; and at least one circuit unit further includes a sensing power supply connection line, a shape of the sensing power supply connection line is a straight line shape or a polyline shape in which a main body portion extends along a first direction, and the sensing power supply line is connected with the sensing power supply connection line to form a network communication structure.

In another aspect, the present disclosure also provides a display apparatus, including the display substrate described above.

In yet another aspect, the disclosure also provides a driving method of a display substrate, which includes a plurality of circuit units, and at least one circuit unit includes a pixel driving circuit, a sensing circuit and a photosensitive device; the pixel driving circuit at least includes a driving transistor and at least one light emitting control transistor, wherein a first end of the light emitting control transistor is connected to a first power supply line, a second end of the light emitting control transistor is connected to a first end of the driving transistor, or the first end of the light emitting control transistor is connected to a second end of the driving transistor, and the second end of the light emitting control transistor is connected to a light emitting device; the sensing circuit at least includes a sensing control transistor, wherein a first end of the sensing control transistor is connected with the photosensitive device, a second end of the sensing control transistor is connected to a sensing signal line, and the light emitting control transistor and the sensing control transistor are different types of transistors; in at least one circuit unit, the light emitting control transistor and the sensing control transistor are connected to a same light emitting signal line, the light emitting signal line is configured to provide a light emitting control signal to the pixel driving circuit; and the driving method includes following periods:
in a first sensing period, controlling, by the light emitting signal line, the sensing circuit to generate a photosensitive current; and
in a second sensing period, controlling, by the light emitting signal line, the pixel driving circuit to output a driving current.

In an exemplary implementation, the controlling, by the light emitting signal line, the sensing circuit to generate a photosensitive current includes: outputting a first signal by the light emitting signal line, turning off so that the light emitting control transistor, turning on the sensing control transistor, and generating a photosensitive current by the sensing circuit.

In an exemplary implementation, the controlling, by the light emitting signal line, the pixel driving circuit to output a driving current includes: outputting a second signal by the light emitting signal line, turning off the sensing control transistor, turning on the light emitting control transistor, and outputting a driving current by the pixel driving circuit.

In another aspect, the present disclosure further provides a preparation method of a display substrate including a plurality of circuit units, the method includes:
forming a pixel driving circuit, a sensing circuit and a photosensitive device in at least one circuit unit; wherein the pixel driving circuit at least includes a driving transistor and at least one light emitting control transistor, wherein a first end of the light emitting control transistor is connected to a first power supply line, and a second end of the light emitting control transistor is connected to a first end of the driving transistor; or the first end of the light emitting control transistor is connected to a second end of the driving transistor, and the second end of the light emitting control transistor is connected to a light emitting device; the sensing circuit at least includes a sensing control transistor, wherein a first end of the sensing control transistor is connected with the photosensitive device, a second end of the sensing control transistor is connected to a sensing signal line, and the light emitting control transistor and the sensing control transistor are different types of transistors; and in at least one circuit unit, the light emitting control transistor and the sensing control transistor are connected to the same light emitting signal line, the light emitting signal line is configured to provide a light emitting control signal to the pixel driving circuit.

Other aspects of the present disclosure may be comprehended after the drawings and the detailed descriptions are read and understood.

### BRIEF DESCRIPTION OF DRAWINGS

Accompany drawings are used to provide understanding of technical solution of the present disclosure, and form a part of the specification. The accompany drawings and embodiments of the present disclosure are adopted to explain the technical solution of the present disclosure, and do not form limitations on the technical solution of the present disclosure.

FIG. 1 is a schematic diagram of a structure of a display apparatus.

FIG. 2 is a schematic diagram of a planar structure of a display substrate.

FIG. 3 illustrates a schematic diagram of a sectional structure of a display substrate.

FIG. 4 is an equivalent circuit diagram of a unit control circuit according to an exemplary embodiment of the present disclosure.

FIG. 5 is a driving timing diagram of the unit control circuit shown in FIG. 4.

FIG. 6 is a schematic diagram of a planar structure of a display substrate according to an exemplary embodiment of the present disclosure.

FIG. 7 is a schematic diagram of structures of the sensing circuit and the photosensitive device in FIG. 6.

FIG. 8 is a schematic diagram of a display substrate after a pattern of a first semiconductor layer is formed according to the present disclosure.

FIG. 9A and FIG. 9B are schematic diagrams of a display substrate after a pattern of a first conductive layer is formed according to the present disclosure.

FIG. 10 is a schematic diagram of a display substrate after a pattern of a photosensitive layer is formed according to the present disclosure.

FIGS. 11A and 11B are schematic diagrams of a display substrate after a pattern of a second conductive layer is formed according to the present disclosure.

FIG. 12A and FIG. 12B are schematic diagrams of a display substrate after a pattern of a second semiconductor layer is formed according to the present disclosure.

FIG. 13A and FIG. 13B are schematic diagrams of a display substrate after a pattern of a third conductive layer is formed according to the present disclosure.

FIG. 14 is a schematic diagram of a display substrate after a pattern of a sixth insulation layer is formed according to the present disclosure.

FIG. 15A and FIG. 15B are schematic views of a display substrate after a pattern of a fourth conductive layer is formed according to the present disclosure.

FIG. 16 is a schematic diagram of a display substrate after a pattern of a first planarization layer is formed according to the present disclosure.

FIG. 17A and FIG. 17B are schematic diagrams of a display substrate after a pattern of a fifth conductive layer is formed according to the present disclosure.

FIG. 18 is a schematic diagram of a display substrate after a pattern of a second planarization layer is formed according to the present disclosure.

FIG. 19A and FIG. 19B are schematic diagrams of a display substrate after a pattern of a sixth conductive layer is formed according to the present disclosure.

### DETAILED DESCRIPTION

To make the objectives, technical solutions, and advantages of the present disclosure clearer, the embodiments of the present disclosure will be described in detail below with reference to the accompany drawings. It is to be noted that implementations may be implemented in multiple different forms. Those of ordinary skills in the art can easily understand such a fact that implementations and contents may be transformed into various forms without departing from the purpose and scope of the present disclosure. Therefore, the present disclosure should not be explained as being limited to the contents recorded in the following implementations only. The embodiments and features in the embodiments of the present disclosure may be randomly combined with each other if there is no conflict.

Scales of the drawings in the present disclosure may be used as a reference in actual processes, but are not limited thereto. For example, a width-length ratio of a channel, a thickness and spacing of each film, and a width and spacing of each signal line may be adjusted according to actual needs. A quantity of pixels in a display substrate and a quantity of sub-pixels in each pixel are not limited to numbers shown in the drawings. The drawings described in the present disclosure are schematic structural diagrams only, and one mode of the present disclosure is not limited to shapes, numerical values, or the like shown in the drawings.

Ordinal numerals “first”, “second”, “third”, etc., in the specification are set not to form limits in numbers but only to avoid confusion between composition elements.

In the specification, for convenience, expressions “central”, “above”, “below”, “front”, “back”, “vertical”, “horizontal”, “top”, “bottom”, “inside”, “outside”, etc., indicating directional or positional relationships are used to illustrate positional relationships between the composition elements, not to indicate or imply that involved devices or elements are required to have specific orientations and be structured and operated with the specific orientations but only to easily and simply describe the present specification, and thus should not be understood as limitations on the present disclosure. The positional relationships between the constituent elements may be changed as appropriate according to a direction according to which each constituent element is described. Therefore, appropriate replacements based on situations are allowed, which is not limited to the expressions in the specification.

In the specification, unless otherwise specified and defined, terms “mounting”, “mutual connection”, and “connection” should be understood in a broad sense. For example, a connection may be fixed connection, or a detachable connection, or an integral connection; it may be a mechanical connection or an electrical connection; it may be a direct connection, or an indirect connection through middleware, or internal communication inside two elements. Those of ordinary skills in the art may understand specific meanings of the above terms in the present disclosure according to specific situations.

In the specification, a transistor refers to an element that at least includes three terminals, i.e., a gate electrode, a drain electrode, and a source electrode. The transistor has a channel region between the drain electrode (drain electrode terminal, drain region, or drain) and the source electrode (source electrode terminal, source region, or source), and a current can flow through the drain electrode, the channel region, and the source electrode. It is to be noted that in the specification, the channel region refers to a region through which a current mainly flows.

In the specification, a first electrode may be a drain electrode, and a second electrode may be a source electrode. Or, the first electrode may be a source electrode, and the second electrode may be a drain electrode. In a case that transistors with opposite polarities are used, or in a case that a direction of a current changes during operation of a circuit, or the like, functions of the “source electrode” and the “drain electrode” are sometimes interchangeable. Therefore, the “source electrode” and the “drain electrode”, as well as the “source terminal” and the “drain terminal”, are interchangeable in the specification.

In the specification, “electrical connection” includes connection of composition elements through an element with a certain electrical action. An “element with a certain electrical action” is not particularly limited as long as electrical signals between the connected constituent elements may be sent and received. Examples of the “element with the certain electrical action” not only include an electrode and a wiring, but also include a switching element such as a transistor, a resistor, an inductor, a capacitor, another element with various functions, etc.

In the specification, “parallel” refers to a state in which an angle formed by two straight lines is −10° or more and 10° or less, and thus also includes a state in which the angle is −5° or more and 5° or less. In addition, “perpendicular” refers to a state in which an angle formed by two straight lines is 80° or more and 100° or less, and thus also includes a state in which the angle is 85° or more and 95° or less.

In the specification, a “film” and a “layer” are interchangeable. For example, a “conductive layer” may be replaced with a “conductive thin film” sometimes. Similarly, an “insulation film” may be replaced with an “insulation layer” sometimes.

Triangle, rectangle, trapezoid, pentagon, hexagon, etc. in this specification are not strictly defined, and they may be approximate triangle, rectangle, trapezoid, pentagon, hexagon, etc. There may be some small deformations caused by tolerance, and there may be chamfer, arc edge, deformation, etc.

In the present disclosure, “about” refers to that a boundary is not defined so strictly and numerical values within a range of process and measurement errors are allowed.

FIG. 1 is a schematic diagram of a structure of a display apparatus. As shown in FIG. 1, the display apparatus may include a timing controller, a data driver, a scan driver, a light emitting driver, and a pixel array. The timing controller is connected with the data driver, the scan driver, and the light emitting driver, respectively, the data driver is connected with a plurality of data signal lines (D1 to Dn) respectively, the scan driver is connected with a plurality of scan signal lines (S1 to Sm) respectively, and the light emitting driver is connected with a plurality of light emitting signal lines (E1 to Eo) respectively. The pixel array may include a plurality of sub-pixels Pxij, wherein i and j may be natural numbers. At least one sub-pixel Pxij may include a circuit unit and a light emitting unit connected with the circuit unit, wherein the circuit unit may at least include a pixel driving circuit, and the pixel driving circuit is connected with a scan signal line, a light emitting signal line, and a data signal line, respectively. In an exemplary implementation, the timing controller may provide the data driver with a gray scale value and a control signal which are suitable for the specification of the data driver, provide the scan driver with a clock signal and a scan start signal and the like which are suitable for the specification of the scan driver, and provide the light emitting driver with a clock signal and an emission stop signal and the like which are suitable for the specification of the light emitting driver. The data driver may generate data voltages to be provided to the data signal lines D1, D2, D3, . . . , and Dn using the grayscale value and the control signal that are received from the timing controller. For example, the data driver may sample the gray scale value using the clock signal and apply a data voltage corresponding to the gray scale value to the data signal lines D1 to Dn by taking a pixel row as a unit, wherein n may be a natural number. The scan driver may generate a scan signals to be provided to the scan signal lines S1, S2, S3, . . . , and Sm by receiving the clock signal and the scan start signal from the timing controller. For example, the scan driver may sequentially provide a scan signal with an on-level pulse to the scan signal lines S1 to Sm. For example, the scan driver may be constructed in a form of a shift register and may generate a scan signal in a manner in which a scan start signal provided in a form of an on-level pulse is transmitted to a next-stage circuit sequentially under control of the clock signal, wherein m may be a natural number. The light emitting driver may receive a clock signal, an emission stop signal, etc., from the timing controller to generate an emission signal to be provided to the light emitting signal lines E1, E2, E3, . . . , and Eo. For example, the light emitting driver may sequentially provide an emission signal with an off-level pulse to the light emitting signal lines E1 to Eo. For example, the light emitting driver may be constructed in a form of a shift register and generate an emission signal in a manner of sequentially transmitting an emission stop signal provided in a form of an off-level pulse to a next-stage circuit under control of the clock signal, wherein o may be a natural number. In an exemplary implementation, the pixel array may be disposed on the display substrate.

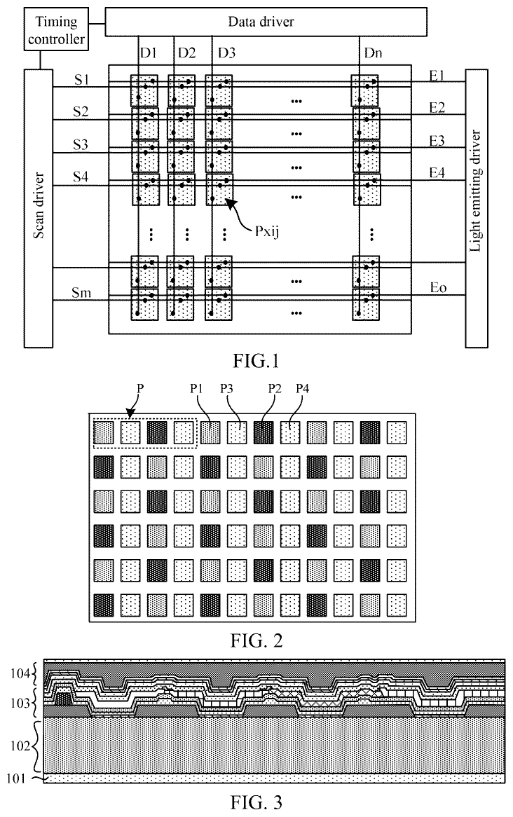

FIG. 2 is a schematic diagram of a planar structure of a display substrate. As shown in FIG. 2, the display substrate may include a plurality of pixel units P arranged in a matrix. At least one pixel unit P may include a first sub-pixel P1 emitting light of a first color, a second sub-pixel P2 emitting light of a second color, a third sub-pixel P3 and a fourth sub-pixel P4 which emit light of a third color. Each sub-pixel may include a circuit unit and a light emitting unit. The circuit unit may at least include a pixel driving circuit, the pixel driving circuit is connected to a scan signal line, a data signal line, and a light emitting signal line respectively, and is configured to receive a data voltage transmitted by the data signal line and output a corresponding current to the light emitting unit under control of the scan signal line and the light emitting signal line. A light emitting unit in each sub-pixel is connected with a pixel driving circuit of the sub-pixel where the light emitting unit is located, and is configured to emit light with corresponding brightness in response to a current output by the pixel driving circuit of the sub-pixel where the light emitting unit is located.

In an exemplary implementation, the first sub-pixel P1 may be a red sub-pixel (R) emitting red light, the second sub-pixel P2 may be a blue sub-pixel (B) emitting blue light, and the third sub-pixel P3 and the fourth sub-pixel P4 may be green sub-pixels (G) emitting green light. In an exemplary implementation, a sub-pixel may be in a shape of a rectangle, a rhombus, a pentagon, or a hexagon. Four sub-pixels may be arranged in a manner of standing side by side horizontally, in a manner of standing side by side vertically, or in a manner of a square.

In an exemplary implementation, a pixel unit may include three sub-pixels, and the three sub-pixels may be arranged side by side horizontally, side by side vertically, or in a delta-shaped arrangement, which is not limited here in the present disclosure.

FIG. 3 is a schematic diagram of a sectional structure of a display substrate, illustrating a structure of four sub-pixels in a display region. As shown in FIG. 3, on a plane perpendicular to the display substrate, the display substrate may include a driving structure layer 102 disposed on a base substrate 101, a light emitting structure layer 103 disposed on one side of the driving structure layer 102 away from the base substrate 101, and an encapsulation structure layer 104 disposed on one side of the light emitting structure layer 103 away from the base substrate 101. In some possible implementations, the display substrate may include another film layer, such as a touch structure layer, which is not limited here in the present disclosure.

In an exemplary implementation, the base substrate 101 may be a flexible substrate, or may be a rigid substrate. The driving structure layer 102 may include a plurality of circuit units, and a circuit unit may at least include a pixel driving circuit composed of a plurality of transistors and a storage capacitor. The light emitting structure layer 103 may include a plurality of light emitting units, and a light emitting unit may at least include a light emitting device composed of an anode, an organic emitting layer, and a cathode. The anode is connected to a pixel driving circuit. The organic emitting layer is connected to the anode. The cathode is connected to the organic emitting layer. The organic emitting layer emits light of a corresponding color under driving of the anode and the cathode. The encapsulation structure layer 104 may include a first encapsulation layer, a second encapsulation layer, and a third encapsulation layer that are stacked. The first encapsulation layer and the third encapsulation layer may be made of an inorganic material, the second encapsulation layer may be made of an organic material, and the second encapsulation layer is arranged between the first encapsulation layer and the third encapsulation layer to form a laminated structure of inorganic material/organic material/inorganic material and ensure that external moisture cannot enter the light emitting structure layer 103.

An exemplary implementation of the present disclosure provides a display substrate. In an exemplary implementation, on a plane perpendicular to the display substrate, the display substrate may include a driving structure layer disposed on a base substrate and a light emitting structure layer disposed on a side of the driving structure layer away from the base substrate. On a plane parallel to the display substrate, the driving structure layer may include a plurality of circuit units composed of a plurality of unit rows and a plurality of unit columns, and at least one circuit unit may include a unit control circuit, which may at least include a pixel driving circuit, a sensing circuit and a photosensitive device, wherein the pixel driving circuit is configured to output a drive current to the connected light emitting device, the sensing circuit is connected to the photosensitive device, and the sensing circuit is configured to generate a photosensitive current according to the connected photosensitive device. The light emitting structure layer may include a plurality of light emitting units, and at least one light emitting unit may include a light emitting device, which is connected to a pixel driving circuit of a corresponding circuit unit. In an exemplary implementation the unit control circuit may be referred to as a pixel driving circuit compatible with light sensing functions.

In an exemplary implementation, the circuit units mentioned in the present disclosure refer to regions divided according to unit control circuits, and the light emitting units mentioned in the present disclosure refer to regions divided according to light emitting devices. In an exemplary implementation, a position and shape of an orthographic projection of a light emitting unit on the base substrate may correspond to a position and shape of an orthographic projection of a circuit unit on the base substrate, or the position and shape of the orthographic projection of the light emitting unit on the base substrate may not correspond to the position and shape of the orthographic projection of the circuit unit on the base substrate.

In an exemplary implementation, the pixel driving circuit may at least include a driving transistor and at least one light emitting control transistor, wherein a first end of the light emitting control transistor is connected to the first power supply line and a second end of the light emitting control transistor is connected to a first end of the driving transistor, or the first end of the light emitting control transistor is connected to a second end of the driving transistor and the second end of the light emitting control transistor is connected to the light emitting device. The sensing circuit at least includes a sensing control transistor, wherein a first end of the sensing control transistor is connected with the photosensitive device, and a second end of the sensing control transistor is connected with the sensing signal line. The light emitting control transistor and the sensing control transistor are different types of transistors; and in at least one circuit unit, the light emitting control transistor and the sensing control transistor are connected to the same light emitting signal line, and the light emitting signal line is configured to provide a light emitting control signal to the pixel driving circuit.

In an exemplary implementation, the light emitting control transistor is a polysilicon transistor, and the sensing control transistor is an oxide transistor; or the light emitting control transistor is an oxide transistor, and the sensing control transistor is a polysilicon transistor.

In an exemplary implementation, the light emitting control transistor at least includes a light emitting control gate electrode, the sensing control transistor at least includes a sensing control gate electrode, the light emitting control gate electrode is directly connected to the light emitting signal line, and the sensing control gate electrode is connected to the light emitting signal line through a light emitting connection electrode.

A display substrate according to an exemplary embodiment of the present disclosure is illustrated below by some examples.

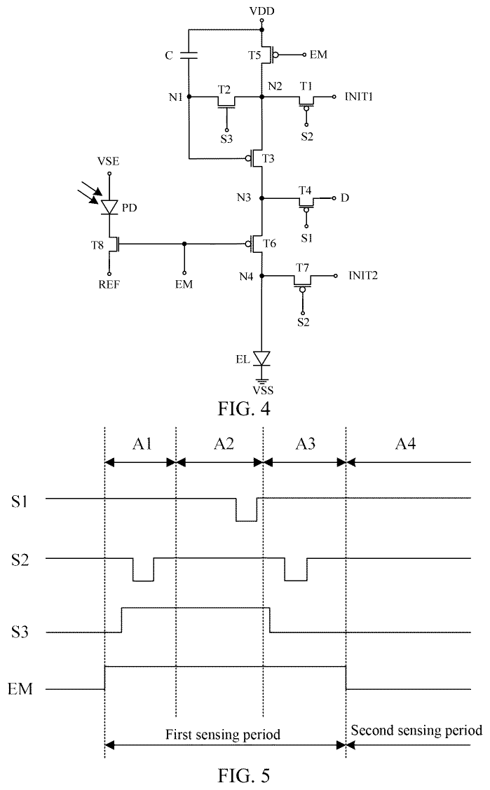

FIG. 4 is an equivalent circuit diagram of a unit control circuit according to an exemplary embodiment of the present disclosure. As shown in FIG. 4, in an exemplary implementation, the unit control circuit may include a pixel driving circuit, a sensing circuit and a photosensitive device. The pixel driving circuit may include seven transistors (a first transistor T1 to a seventh transistor T7) and one storage capacitor C, which is a 7T1C structure, and the pixel driving circuit is connected with eight signal lines (a first scan signal line S1, a second scan signal line S2, a third scan signal line S3, a light emitting signal line EM, a first initial signal line INIT1, a second initial signal line INIT2, a first power supply line VDD and a data signal line D), respectively. The sensing circuit may include one transistor (an eighth transistor T8), and is connected to two signal lines (the light emitting signal line EM and a sensing signal line REF), respectively. The photosensitive device PD may include a first electrode, a photosensitive layer, and a second electrode; and a first electrode of the photosensitive device PD is connected to a sensing power supply line VSE, and a second electrode of the photosensitive device PD is connected to a first electrode of the eighth transistor T8.

In an exemplary implementation, the pixel driving circuit may include a first node N1, a second node N2, a third node N3, and a fourth node N4. Herein, the first node N1 is respectively connected to a first electrode of the second transistor T2, a gate electrode of the third transistor T3 and a first end of the storage capacitor C, the second node N2 is respectively connected to a second electrode of the first transistor T1, a second electrode of the second transistor T2, a first electrode of the third transistor T3 and a second electrode of the fifth transistor T5, the third node N3 is respectively connected to a second electrode of the third transistor T3, a second electrode of the fourth transistor T4 and a first electrode of the sixth transistor T6, and the fourth node N4 is respectively connected to a second electrode of the sixth transistor T6 and a second electrode of the seventh transistor T7.

In an exemplary implementation, the first end of the storage capacitor C is connected with the first node N1, and a second end of the storage capacitor C is connected with the first power supply line VDD.

In an exemplary implementation, the first transistor T1 may be referred to as a first initialization transistor, a gate electrode of the first transistor T1 is connected to the second scan signal line S2, a first electrode of the first transistor T1 is connected to the first initial signal line INIT1, and a second electrode of the first transistor T1 is connected to the second node N2.

In an exemplary implementation, the second transistor T2 may be referred to as a compensation transistor, a gate electrode of the second transistor T2 is connected with the third scan signal line S3, a first electrode of the second transistor T2 is connected with the first node N1, and a second electrode of the second transistor T2 is connected with the second node N2.

In an exemplary implementation, the third transistor T3 may be referred to as a driving transistor, a gate electrode of the third transistor T3 is connected to the first node N1, a first electrode of the third transistor T3 is connected to the second node N2, and a second electrode of the third transistor T3 is connected to the third node N3.

In an exemplary implementation, the fourth transistor T4 may be referred to as a data writing transistor, a gate electrode of the fourth transistor T4 is connected to the first scan signal line S1, a first electrode of the fourth transistor T4 is connected to the data signal line D, and a second electrode of the fourth transistor T4 is connected to the third node N3.

In an exemplary implementation, the fifth transistor T5 may be referred to as a first light emitting control transistor, a gate electrode of the fifth transistor T5 is connected to the light emitting signal line EM, a first electrode of the fifth transistor T5 is connected to the first power supply line VDD, and a second electrode of the fifth transistor T5 is connected to the second node N2.

In an exemplary implementation, the sixth transistor T6 may be referred to as a second light emitting control transistor, a gate electrode of the sixth transistor T6 is connected to the light emitting signal line EM, a first electrode of the sixth transistor T6 is connected to the third node N3, and a second electrode of the sixth transistor T6 is connected to the fourth node N4.

In an exemplary implementation, the seventh transistor T7 may be referred to as a second initialization transistor, a gate electrode of the seventh transistor T7 is connected to the second scan signal line S2, the first electrode of the seventh transistor T7 is connected to the second initial signal line INIT2, and a second electrode of the seventh transistor T7 is connected to the fourth node N4.

In the exemplary implementation, a gate electrode of the eighth transistor T8 is connected to the light emitting signal line EM, a first electrode of the eighth transistor T8 is connected to a second electrode of the photosensitive device PD, and a second electrode of the eighth transistor T8 is connected to the sensing signal line REF.

In an exemplary implementation, a first electrode of a light emitting device EL is connected to the fourth node N4, and a second electrode of the light emitting device EL is connected to the second power supply line VSS. The light emitting device EL may be an OLED, including a first electrode (an anode), an organic light emitting layer, and a second electrode (an cathode) which are stacked, or may be a QLED including a first electrode (an anode), a quantum dot light emitting layer, and a second electrode (a cathode) which are stacked.

In an exemplary implementation, signals of the first power supply line VDD and the sensing power supply line VSE are high-level signals provided continuously, and signals of the second power supply line VSS are low-level signals provided continuously.

In an exemplary implementation, the first transistor T1 to the seventh transistor T7 in the pixel driving circuit may be P-type transistors or may be N-type transistors. In some possible implementations, the first transistor T1 to the seventh transistor T7 may include a P-type transistor and an N-type transistor.

In an exemplary implementation, the first transistor T1 to the seventh transistor T7 in the pixel driving circuit may be low temperature poly silicon transistors, or may be oxide transistors, or may be low temperature poly silicon transistors and oxide transistors. An active layer of a low temperature poly silicon transistor is made of Low Temperature Poly silicon (LTPS for short), and an active layer of an oxide transistor is made of an oxide semiconductor (Oxide). The low temperature polysilicon transistor has advantages such as a high migration rate and fast charging, and the oxide transistor has advantages such as a low drain current. The low temperature polysilicon transistor and the oxide transistor are integrated on one display substrate to form a Low Temperature Polycrystalline Oxide (LTPO for short) display substrate, such that advantages of the low temperature polysilicon transistor and the metal oxide transistor may be utilized, low-frequency drive may be achieved, power consumption may be reduced, and display quality may be improved.

As shown in FIG. 4, in the present exemplary embodiment, the second transistor T2 in the pixel driving circuit and the eighth transistor T8 in the sensing circuit may be oxide transistors (N-type transistors), and the first transistors T1, the third transistors T3 to the seventh transistors T7 may be low-temperature polysilicon transistors (P-type transistors).

FIG. 5 is a driving timing diagram of the unit control circuit shown in FIG. 4, wherein the second transistors T2 and the eighth transistors T8 are N-type oxide transistors, and the first transistors T1, the third transistors T3 to the seventh transistors T7 are P-type low-temperature polysilicon transistors. As shown in FIG. 5, a working process of the pixel driving circuit in the unit control circuit may include following stages.

The first stage A1 is referred to as a reset stage. A signal of the second scan signal line S2 is a low-level signal, signals of the first scan signal line S1, the third scan signal line S3, and the light emitting signal line EM are high-level signals, the first transistor T1, the second transistor T2, and the seventh transistor T7 are turned on, and the other transistors are turned off.

The first transistor T1 is turned on, such that a first initial signal of the first initial signal line INIT1 is provided to the second node N2 to initialize (reset) the second node N2. The second transistor T2 is turned on, such that the first node N1 and the second node N2 are turned on, and the first initial signal initializes (resets) the first node N1 to clear the original charge in the storage capacitor. The seventh transistor T7 is turned on, such that a second initial signal of the second initial signal line INIT2 is provided to the fourth node N4 to initialize (reset) the first electrode of the light emitting device EL to clear the original charge in the first electrode of the light emitting device EL.

A second stage A2 is referred to as a data writing stage. A signal of the first scan signal line S1 is a low-level signal, signals of the second scan signal line S2, the third scan signal line S3, and the light emitting signal line EM are high-level signals, such that the second and fourth transistors T2 and T4 are turned on, and the other transistors (except the third transistor T3) are turned off.

Since the first node N1 is at a low level, the third transistor T3 is continuously turned on. The fourth transistor T4 is turned on, such that a data signal of the data signal line D is provided to the first node N1 through the third node N3 and the turned-on third transistor T3, and a difference between a data voltage of the data signal and a threshold voltage of the third transistor T3 is charged to the storage capacitor C. The second transistor T2 is turned on, such that the first node N1 and the second node N2 are turned on, and a potential of the second node N2 is the same as that of the first node N1.

The third stage A3 is referred to as a reset stage of the second node N2. Signals of the second scan signal line S2 and the third scan signal line S3 are low-level signals, and signals of the first scan signal line S1 and the light emitting signal line EM are high-level signals, such that the first transistors T1 and the seventh transistors T7 are turned on, and the other transistors (except the third transistor T3) are turned off.

The first transistor T1 is turned on, such that a first initial signal of the first initial signal line INIT1 is provided to the second node N2 to reset the second node N2. Since the third transistor T3 is continuously turned on at this stage, the first initial signal is provided to the third node N3 to reset the third node N3. The seventh transistor T7 is turned on, such that a second initial signal of the second initial signal line INIT2 is provided to the fourth node N4 to initialize the first electrode of the light emitting device EL. In this stage, the second node N2, the third node N3 and the fourth node N4 are reset, which may eliminate and improve hysteresis bias due to a difference in gray scales between adjacent pixels, reduce the hysteresis bias, and also periodically reset the OLED anode to improve the low-frequency flickering.

The fourth stage A4 is referred to as a light emitting stage. Signals of the third scan signal line S3 and the light emitting signal line EM are low-level signals, and signals of the first scan signal line S1 and the second scan signal line S2 are high-level signals, such that the fifth and sixth transistors T5 and T6 are turned on, and the other transistors (except the third transistor T3) are turned off.

The fifth transistor T5 and the sixth transistor T6 are turned on such that a first power supply voltage outputted from the first power supply line VDD provides a driving current to a first electrode of the light emitting device EL through the fifth transistor T5, the third transistor T3 and the sixth transistor T6 which are turned on to drive the light emitting device EL to emit light.

During a driving process of the pixel driving circuit, a driving current flowing through the third transistor T3 (the driving transistor) is determined by a voltage difference between the gate electrode and the first electrode thereof, and the driving current of the third transistor T3 of each pixel driving circuit is not affected by the threshold voltage of the third transistor T3.

As shown in FIG. 5, a working process of the sensing circuit in the unit control circuit may include following sensing periods.

The first sensing period including a first stage A1 (a reset stage), a second stage A2 (a data writing stage), and a third stage A3 (a second node N2 reset stage) of the pixel driving circuit, the signal of the light emitting signal line EM is a high-level signal, the eighth transistor T8 is turned on, and the sensing circuit generates a photosensitive current according to the connected photosensitive device PD.

The second sensing period includes a fourth stage A4 (a light emitting stage) of the pixel driving circuit, a signal of the light emitting signal line EM is a low-level signal, the eighth transistor T8 is turned off, and the sensing circuit is not working.

In an exemplary implementation, the sensing circuit and the photosensitive device PD may be used for fingerprint recognition and may be referred to as a fingerprint sensor, the eighth transistor T8 may be referred to as a switching transistor of the fingerprint sensor, and the light emitting signal line EM providing a light emitting control signal to the pixel driving circuit may be multiplexed as a control signal of the fingerprint sensor.

In an exemplary implementation, the unit control circuit of the present disclosure includes two functional portions, the first transistor T1 to the seventh transistor T7 are switching transistors for display, the eighth transistor T8 is a switching transistor for fingerprint recognition, the two functional portions share a gate driving circuit (GOA) outputting a light emitting control signal, and the light emitting signal line EM serves as a control signal for display light emitting on one hand, and a control signal for fingerprint recognition on the other hand. When a signal of the light emitting signal line EM is a high-level signal, the pixel driving circuit performs reset and data writing, and the fingerprint sensor performs scanning and sampling of the fingerprint signal. When a signal of the light emitting signal line EM is a low-level signal, the pixel driving circuit outputs a driving current, and the fingerprint sensor stops sampling.

In an exemplary implementation, the fingerprint sensor is provided with two DC signals, such as a photosensitive power supply signal (Vsensor) and a photosensitive signal (Vref), wherein a voltage of the photosensitive power supply signal may be from 1 V to 10 V, and a reference voltage of the photosensitive signal may be preset to be about 0.2 V. For one unit row, when the light emitting signal line EM outputs a high-level signal, the pixel driving circuit of the present unit row performs reset and data writing, the eighth transistor T8 of the sensing circuit is turned on, and the light emitted from the light emitting unit is reflected into the fingerprint sensor built into the circuit unit through a peak and valley of the fingerprint, so as to achieve a photosensitive current signal sampling controlled by the unit row. The light emitting signal line EM scans each unit row sequentially, so that the fingerprint sensors at different positions on the display substrate form photosensitive currents of different sizes. The photosensitive current is transmitted to an external processing unit (such as an analog-digital conversion ADC unit) through the sensing signal line, which may effectively obtain a distribution of fingerprints and achieve a fingerprint identification function. Since the fingerprint sensor is disposed in the circuit unit, pitches between the fingerprint sensor and the pixel driving circuits are the same, and the fingerprint sensing accuracy is high. Since a scan width of the gate driving circuit outputting the light emitting signal is adjustable, the fingerprint sampling time and period may be flexibly adjusted, effectively improving the sampling accuracy.

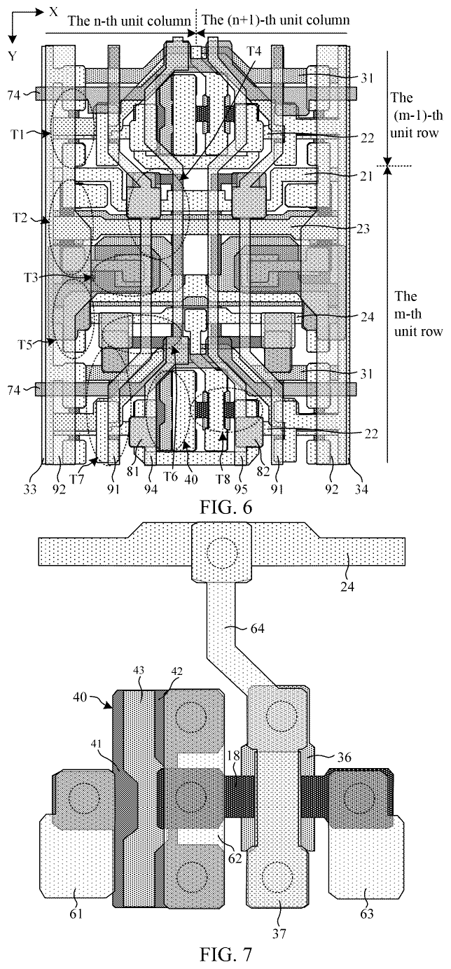

FIG. 6 is a schematic diagram of a planar structure of a display substrate according to an exemplary embodiment of the present disclosure. In an exemplary implementation, the display substrate may include a plurality of circuit units, the plurality of circuit units may form a plurality of unit rows and a plurality of unit columns, the plurality of circuit units in each unit row are sequentially arranged along the first direction X, and the plurality of unit rows are sequentially arranged along a second direction Y, constituting a circuit unit array arranged in an array, and the first direction X and the second direction Y intersect. As shown in FIG. 6, the at least one circuit unit may include a unit control circuit, which may at least include a pixel driving circuit, a sensing circuit, and a photosensitive device, wherein the sensing circuit is connected to the photosensitive device, the pixel driving circuit is configured to output a driving current to the connected light emitting device, and the sensing circuit is configured to generate a photosensitive current according to the connected photosensitive device.

In an exemplary implementation, the pixel driving circuit of the at least one circuit unit may at least include a storage capacitor and a plurality of transistors, wherein the storage capacitor may include a stacked first electrode plate and a second electrode plate, and the plurality of transistors may include a first transistor T1 as a first initialization transistor, a second transistor T2 as a compensation transistor, a third transistor T3 as a driving transistor, a fourth transistor T4 as a data writing transistor, a fifth transistor T5 as a first light emitting control transistor, a sixth transistor T6 as a second light emitting control transistor, and a seventh transistor T7 as a second initialization transistor. The sensing circuit of the at least one circuit unit may include an eighth transistor T8 as a sensing control transistor. Herein, the second transistor T2 and the eighth transistor T8 are oxide transistors, and the first transistor T1, the third transistor T3 to the seventh transistor T7 are low-temperature polysilicon transistors.

In an exemplary implementation, a gate electrode of the first transistor T1 is connected with a second scan signal line 22, a first electrode of the first transistor T1 is connected with a first initial signal line 31, and a second electrode of the first transistor T1 is connected with a first electrode of the third transistor T3.

In the exemplary implementation, a gate electrode of the second transistor T2 is connected to a third scan signal line 23, a first electrode of the second transistor T2 is connected to a gate electrode of the third transistor T3, and a second electrode of the second transistor T2 is connected to a first electrode of the third transistor T3.

In an exemplary implementation, the gate electrode of the third transistor T3 may serve as a first electrode plate of the storage capacitor, and the first electrode of the third transistor T3 is connected to the second electrode of the first transistor T1 and the second electrode of the second transistor T2, respectively.

In an exemplary implementation, a gate electrode of the fourth transistor T4 is connected to a first scan signal line 21, a first electrode of the fourth transistor T4 is connected to a data signal line 91, and a second electrode of the fourth transistor T4 is connected to the second electrode of the second transistor T3.

In an exemplary implementation, a gate electrode of the fifth transistor T5 is connected to a light emitting signal line 24, a first electrode of the fifth transistor T5 is connected with a first power supply line 92, and a second electrode of the fifth transistor T5 is connected with the first electrode of the third transistor T3.

In an exemplary implementation, a gate electrode of the sixth transistor T6 is connected to the light emitting signal line 24, a first electrode of the sixth transistor T6 is connected to the second electrode of the third transistor T3, and a second electrode of the sixth transistor T6 is connected to a second electrode of the seventh transistor T7.

In an exemplary implementation, a gate electrode of the seventh transistor T7 is connected with a second scan signal line 22, a first electrode of the seventh transistor T7 is connected with a second initial signal line 32, and a second electrode of the seventh transistor T7 is connected with a second electrode of the sixth transistor T6.

In the exemplary implementation, a gate electrode of the eighth transistor T8 is connected to the light emitting signal line 24, a first electrode of the eighth transistor T8 is connected to the photosensitive device, and a second electrode of the eighth transistor T8 is connected to the sensing signal line 95.

In an exemplary implementation, the photosensitive device 40 of the at least one circuit unit may include a photosensitive first electrode, a photosensitive second electrode, and a photosensitive layer disposed between the photosensitive first electrode and the photosensitive second electrode, wherein the photosensitive first electrode is connected to the sensing power supply line 94, and the photosensitive second electrode is connected to the first electrode of the eighth transistor T8.

In an exemplary implementation, the first scan signal line 21, the second scan signal line 22, the third scan signal line 23, the light emitting signal line 24, the first initial signal line 31, and the second initial signal line 32 may be a straight line shape or a polyline shape in which a main body portion extends along the first direction X, and the data signal line 91, the first power supply line 92, the sensing power supply line 94 and the sensing signal line 95 may be a straight line shape or a polyline shape in which a main body portion extends along the second direction Y.

In the present disclosure, “A extends along a B direction” refers to that A may include a main portion and a secondary portion connected with the main portion, wherein the main portion is a line, a line segment, or a strip-shaped body, the main body portion extends along the B direction, and a length of the main portion extending along the B direction is greater than a length of the secondary portion extending along another direction. In following description, “A extends along a B direction” means “a main body portion of A extends along a B direction”.

In an exemplary implementation, the at least one circuit unit may also include a sensing power supply connection line 74 in which a main body portion extends along the first direction X, and the sensing power supply connection line 74 in which the main body portion extends along the first direction X and the sensing power supply line 94 in which a main body portion extends along the second direction Y are connected to each other to form a network communication structure for transmitting a photosensitive power supply signal on the display substrate.

In an exemplary implementation, the at least one circuit unit may also include a first initial connection line 33 in which a main body portion extends along the second direction Y, the first initial signal line 31 in which a main body portion extends along the first direction X and the first initial connection line 33 in which a main body portion extends along the second direction Y are connected to each other to form a network communication structure for transmitting the first initial signal on the display substrate.

In an exemplary implementation, the at least one circuit unit may also include a second initial connection line 34 in which a main body portion extends along the second direction Y, the second initial signal line 32 in which a main body portion extends along the first direction X and the second initial connection line 34 in which a main body portion extends along the second direction Y are connected to each other to form a network communication structure for transmitting the second initial signal on the display substrate.

In an exemplary implementation, in at least one circuit unit, the fifth transistor T5 and the sixth transistor T6 of the pixel driving circuit and the eighth transistor T8 of the sensing circuit are connected to the same light emitting signal line 24, and the same light emitting signal line 24 controls the fifth transistor T5, the sixth transistor T6 and the eighth transistor T8 to be turned on or turned off.

In an exemplary implementation, when the light emitting signal line 24 outputs a first signal, the fifth transistor T5 and the sixth transistor T6 are turned off, the eighth transistor T8 is turned on, and the sensing circuit generates a photosensitive current. When the light emitting signal line 24 outputs a second signal, the eighth transistor T8 is turned off, the fifth transistor T5 and the sixth transistor T6 are turned on, and the pixel driving circuit outputs a driving current. For example, in the first sensing period, the light emitting signal line 24 controls the sensing circuit to generate a photosensitive current; and in the second sensing period, the light emitting signal line 24 controls the pixel driving circuit to output a driving current.

In an exemplary implementation, the fifth transistor T5 and the sixth transistor T6 are one type of transistors, and the eighth transistor T8 is another type of transistor. For example, the fifth transistors T5 and the sixth transistors T6 may be polysilicon transistors (P-type transistors), and the eighth transistor T8 may be oxide transistors (N-type transistors). As another example, the fifth transistors T5 and the sixth transistors T6 may be oxide transistors (N-type transistors), and the eighth transistor T8 may be polysilicon transistors (a P-type transistor).

FIG. 7 is a schematic diagram of structures of the sensing circuit and the photosensitive device in FIG. 6. As shown in FIGS. 6 and 7, in an exemplary implementation, the fifth transistor T5 may at least include a fifth gate electrode, the sixth transistor T6 may at least include a sixth gate electrode, and the fifth gate electrode and the sixth gate electrode may serve as the light emitting control gate electrodes of the present disclosure. The eighth transistor T8 may at least include an eighth active layer 18, an eighth bottom gate electrode 36, and an eighth top gate electrode 37, and the eighth bottom gate electrode 36 and the eighth top gate electrode 37 may serve as the sensing control gate electrode of the present disclosure. The fifth gate electrode and the sixth gate electrode may be directly connected to the light emitting signal line 24, and the eighth bottom gate electrode 36 and the eighth top gate electrode 37 may be connected to the light emitting signal line 24 through the light emitting connection electrode 64.

In an exemplary implementation, in a direction perpendicular to the display substrate, the display substrate may include a plurality of conductive layers, the fifth gate electrode, the sixth gate electrode, and the light emitting signal line 24 may be disposed in the same conductive layer, the light emitting signal line 24 may be disposed in different conductive layers with the eighth bottom gate electrode 36 and the eighth top gate electrode 37, and the light emitting connection electrode 64 may be disposed in different conductive layers with the eighth bottom gate electrode 36 and the eighth top gate electrode 37.

In an exemplary implementation, a plurality of conductive layers may at least include a first conductive layer, a second conductive layer, a third conductive layer, and a fourth conductive layer disposed sequentially in a direction away from the base substrate. The fifth gate electrode, the sixth gate electrode, and the light emitting signal line 24 may be disposed in the first conductive layer, and the fifth gate electrode, the sixth gate electrode, and the light emitting signal line 24 may be of an integral structure connected to each other. The eighth bottom gate electrode 36 may be disposed in the second conductive layer, the eighth top gate electrode 37 may be disposed in the third conductive layer, and the light emitting connection electrode 64 may be disposed in the fourth conductive layer. The light emitting connection electrode 64 is respectively connected to the light emitting signal line 24, the eighth bottom gate electrode 36, and the eighth top gate electrode 37 through a via hole.

In an exemplary implementation, the photosensitive device 40 may at least include a photosensitive first electrode 41, a photosensitive second electrode 42, and a photosensitive layer 43 disposed between the photosensitive first electrode 41 and the photosensitive second electrode 42. The photosensitive first electrode 41, the photosensitive layer 43, and the photosensitive second electrode 42 may be arranged along the first direction X, the photosensitive first electrode 41 may be disposed on a side of the photosensitive layer 43 in an opposite direction of the first direction X, and the photosensitive second electrode 42 may be disposed on a side of the photosensitive layer 43 in the first direction X, forming a photodiode with a transverse configuration.

In an exemplary implementation, in a direction perpendicular to the display substrate, the display substrate may include a first semiconductor layer and a second semiconductor layer disposed on a side of the first semiconductor layer away from the base substrate, the photosensitive first electrode 41 and the photosensitive second electrode 42 may be formed by performing a conductorization treatment on the first semiconductor layer, the photosensitive layer 43 may be formed by doping the first semiconductor layer, and the eighth active layer 18 as a sensing active layer may be disposed in the second semiconductor layer.

In an exemplary implementation, the at least one circuit unit may also include an eleventh connection electrode 61 and a thirty-first connection electrode 81, and the photosensitive first electrode 41 may be connected to the sensing power supply line 94 through the eleventh connection electrode 61 and the thirty-first connection electrode 81.

In an exemplary implementation, the at least one circuit unit may also include a twelfth connection electrode 62, and the photosensitive second electrode 42 may be connected to a first region of the eighth active layer 18 through the twelfth connection electrode 62.

In an exemplary implementation, the at least one circuit unit may also include a thirteenth connection electrode 63 and a thirty-second connection electrode 82, and the second region of the eighth active layer 18 may be connected to the sensing signal line 95 through the thirteenth connection electrode 63 and the thirty-second connection electrode 82.

In an exemplary implementation, the eleventh connection electrode 61, the twelfth connection electrode 62, and the thirteenth connection electrode 63 and the light emitting connection electrode 64 may be disposed in the same layer and formed synchronously through the same patterning process.

In an exemplary implementation, in a direction perpendicular to the display substrate, the display substrate may also include a fifth conductive layer disposed on a side of the fourth conductive layer away from the base substrate, and a sixth conductive layer disposed on a side of the fifth conductive layer away from the base substrate. The thirty-first connection electrode 81 and the thirty-second connection electrode 82 may be provided in the fifth conductive layer, the thirty-first connection electrode 81 is connected to the eleventh connection electrode 61 through a via hole, and the thirty-second connection electrode 82 is connected to the thirteenth connection electrode 63 through a via hole. The sensing power supply line 94 and the sensing signal line 95 may be disposed in the sixth conductive layer, the sensing power supply line 94 is connected to the thirty-first connection electrode 81 through a via hole, and the sensing signal line 95 being connected to the thirty-second connection electrode 82 through a via hole.

Exemplary description is made below through a preparation process of a display substrate. A “patterning process” mentioned in the present disclosure includes a treatment such as deposition of a film layer, photoresist coating on a film layer, mask exposure, development, etching, and photoresist stripping for a metal material, an inorganic material, or a transparent conductive material, and includes a treatment such as organic material coating, mask exposure, and development for an organic material. Deposition may be any one or more of sputtering, evaporation, and chemical vapor deposition, coating may be any one or more of spray coating, spin coating, and inkjet printing, and etching may be any one or more of dry etching and wet etching, the present disclosure is not limited thereto. A “thin film” refers to a layer of thin film made of a certain material on a base substrate using deposition, coating, or other processes. If the “thin film” does not need to be processed through a patterning process in the entire manufacturing process, the “thin film” may also be called a “layer”. If the “thin film” needs to be processed through the patterning process in the entire manufacturing process, the “thin film” is called a “thin film” before the patterning process is performed and is called a “layer” after the patterning process is performed. At least one “pattern” is contained in the “layer” which has been processed through the patterning process. “A and B are arranged in a same layer” in the present disclosure means that A and B are formed simultaneously through a same patterning process, and a “thickness” of a film layer is a dimension of the film layer in a direction perpendicular to a display substrate. In an exemplary implementation of the present disclosure, “an orthographic projection of B is within a range of an orthographic projection of A” or “an orthographic projection of A contains an orthographic projection of B” refers to that a boundary of the orthographic projection of B falls within a range of a boundary of the orthographic projection of A, or the boundary of the orthographic projection of A coincides with the boundary of the orthographic projection of B.

In an exemplary implementation, taking fourth circuit units (2 unit rows and 2 unit columns) as an example, the preparation process of the display substrate may include the following operations.

(1) A pattern of a first semiconductor layer is formed. In an exemplary implementation, forming the pattern of the first semiconductor layer may include: sequentially depositing a first insulating thin film and a first semiconductor thin film on a base substrate, patterning the first semiconductor thin film by a patterning process to form a first insulation layer disposed on the base substrate, and the pattern of the first semiconductor layer disposed on the first insulation layer, as shown in FIG. 8.

In an exemplary implementation, a pattern of a first semiconductor layer of each circuit unit may at least include a first active layer 11 of a first transistor T1, a third active layer 13 of a third transistor T3 to a seventh active layer 17 of a seventh transistor T7, and the third active layer 13 to the seventh active layer 17 are of an integral structure connected to each other.

In an exemplary implementation, in the first direction X, the fourth active layer 14 and the sixth active layer 16 may be located on a side of the third active layer 13 in the present circuit unit, and the first active layer 11 and the fifth active layer 15 may be located on the other side of the third active layer 13 in the present circuit unit. In the second direction Y, the fifth active layer 15, the sixth active layer 16, and the seventh active layer 17 may be located on a side of the third active layer 13 in the present circuit unit in the second direction Y, and the first active layer 11 and the fourth active layer 14 may be located on a side of the third active layer 13 in the present circuit unit in an opposite direction of the second direction Y.

In an exemplary implementation, the first active layer 11 of the pixel driving circuit in the present circuit unit may be disposed in the circuit unit of the previous unit row, and located on a side of the seventh active layer 17 in the circuit unit of the previous unit row in the first direction X or in an opposite direction of the first direction X. For example, the first active layer 11 of the pixel driving circuit in the circuit unit of the m-th unit row may be disposed in the circuit unit of the (m−1)-th unit row. As another example, the first active layer 11 of the pixel driving circuit in the circuit unit of the (m+1)-th unit row may be disposed in the circuit unit of the m-th unit row.

In an exemplary implementation, the third active layer 13 may be in a shape of an “Ω”, the first active layer 11, the fifth active layer 15 and the seventh active layer 17 may be in a shape of an “I”, and the fourth active layer 14 and the sixth active layer 16 may be in a shape of an “L”.

In an exemplary implementation, the first active layer 11, the third active layer 13 to the seventh active layer 17 may each include a first region, a second region, and a channel region located between the first region and the second region. In an exemplary implementation, a first region 13-1 of the third active layer is interconnected with a second region 15-2 of the fifth active layer, and the first region 13-1 of the third active layer may serve as a second region 15-2 of the fifth active layer. A second region 13-2 of the third active layer, a second region 14-2 of the fourth active layer, and a first region 16-1 of the sixth active layer are connected to each other, and the second region 13-2 of the third active layer may simultaneously serve as a second region 14-2 of the fourth active layer and a first region 16-1 of the sixth active layer. A second region 16-2 of the sixth active layer and a second region 17-2 of the seventh active layer are connected to each other, and the second region 16-2 of the sixth active layer may serve as a second region 17-2 of the seventh active layer. A first region 11-1 of the first active layer, a second region 11-2 of the first active layer, a first region 14-1 of the fourth active layer, a first region 15-1 of the fifth active layer and a first region 17-1 of the seventh active layer may be individually disposed.

In an exemplary implementation, the first semiconductor layer may also include a photosensitive active layer 19. A shape of the photosensitive active layer 19 may be a block shape, may be disposed in the circuit unit of the n-th unit column, and may be located on a side of the seventh active layer 17 in the first direction X.

In an exemplary implementation, the photosensitive active layer 19 may include a photosensitive first region 19-1, a photosensitive second region 19-2, and a photosensitive region 19-3 located between the photosensitive first region 19-1 and the photosensitive second region 19-2, wherein the photosensitive first region 19-1 may be disposed on a side of the photosensitive region 19-3 in an opposite direction of the first direction X (on a side close to the seventh active layer 17) and is configured to be connected to an eleventh connection electrode formed subsequently, the photosensitive second region 19-2 may be disposed on a side of the photosensitive region 19-3 in the first direction X (on a side away from the seventh active layer 17) and is configured to be connected to a twelfth connection electrode formed subsequently.

In an exemplary implementation, the first active layers 11, the third active layers 13 to the seventh active layers 17 of the adjacent unit columns may be mirrored symmetrical with respect to a centerline, which is a straight line located between the adjacent unit columns and extending along the second direction Y. For example, the first active layers 11, the third active layers 13 to the seventh active layers 17 of the n-th unit column and the n+1 unit column may be mirrored symmetrical with respect to the centerline.

In an exemplary implementation, the first semiconductor layer may be made of poly Silicon (p-Si), i.e. the first transistor T1 and the third transistor T3 to the seventh transistor T7 are LTPS transistors. In an exemplary implementation, the patterning the first semiconductor thin film through the patterning process may include: forming an amorphous silicon (a-si) thin film on the first insulation thin film, dehydrogenating the amorphous silicon thin film, and crystallizing the dehydrogenated amorphous silicon thin film to form a poly silicon thin film. Subsequently, the poly silicon thin film is patterned to form the pattern of the first semiconductor layer.

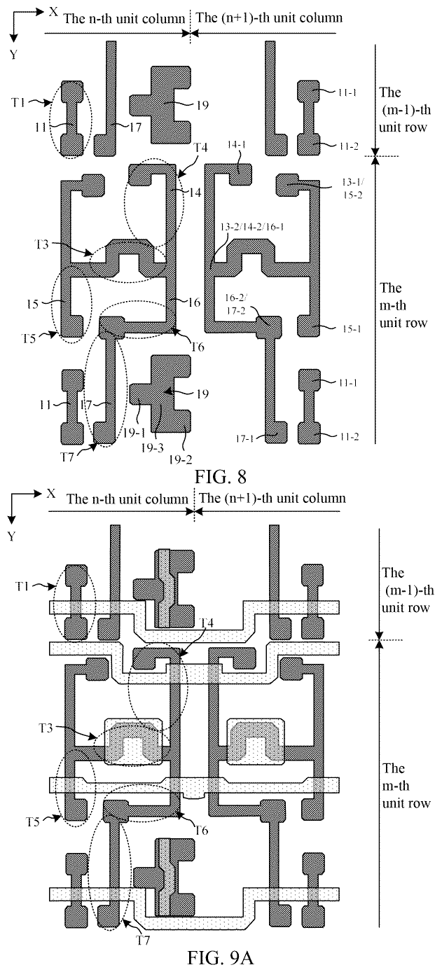

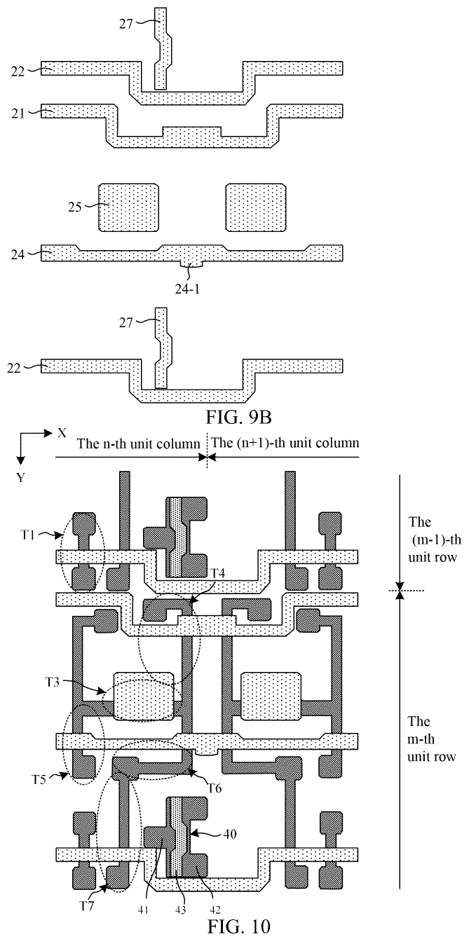

(2) A pattern of a first conductive layer is formed. In an exemplary implementation, forming the pattern of the first conductive layer may include: depositing sequentially a second insulation thin film and a first conductive thin film on the base substrate on which the aforementioned patterns are formed, and patterning the first conductive thin film through a patterning process to form a second insulation layer that covers the pattern of the first semiconductor layer and form the pattern of the first conductive layer disposed on the second insulation layer, as shown in FIG. 9A and FIG. 9B, and FIG. 9B is a schematic plan view of the first conductive layer in FIG. 9A. In an exemplary implementation, the first conductive layer may be referred to as a first gate metal (GATE1) layer.

In an exemplary implementation, the pattern of the first conductive layer of each circuit unit may at least include the first scan signal line 21, the second scan signal line 22, the light emitting signal line 24, the first electrode plate 25 of the storage capacitor.

In an exemplary implementation, the first electrode plate 25 may be in a shape of a rectangle, and a chamfer may be provided at a corner of the rectangle. An orthographic projection of the first electrode plate 25 on the base substrate is at least partially overlapped with an orthographic projection of the third active layer of the third transistor T3 on the base substrate. In an exemplary implementation, the first electrode plate 25 may serve as one plate of the storage capacitor and a gate electrode of the third transistor T3 simultaneously.

In an exemplary implementation, a shape of the first scan signal line 21 may be a straight line shape or a polyline shape in which a main body portion extends along the first direction X, the first scan signal line 21 may be located at a side of the first electrode plate 25 in an opposite direction of the second direction Y, and a region where the first scan signal line 21 is overlapped with the fourth active layer serves as a gate electrode of the fourth transistor T4.

In an exemplary implementation, a shape of the second scan signal line 22 may be a straight line shape or a polyline shape in which a main body portion extends along the first direction X, the second scan signal line 22 may be located on a side of the first electrode plate 25 in the second direction Y, a region where the second scan signal line 22 is overlapped with the first active layer serves as the gate electrode of the first transistor T1, and a region where the second scan signal line 22 is overlapped with the seventh active layer serves as the gate electrode of the seventh transistor T7.

In an exemplary implementation, since the first active layer of the present circuit unit is disposed in the previous unit row, in the pixel driving circuit of the present circuit unit, the first transistor T1 is controlled by the second scan signal line 22 of the previous unit row, and the seventh transistor T7 is controlled by the second scan signal line 22 of the present unit row, that is, the second scan signal line 22 of the present unit row controls the seventh transistor T7 of the pixel driving circuit in the circuit unit of the present unit row to be turned on and off, and controls the first transistor T1 of the pixel driving circuit in the circuit unit of the next unit row to be turned on and off.

In an exemplary implementation, a shape of the light emitting signal line 24 may be a straight line shape or a polyline shape in which a main body portion extends along the first direction X, the light emitting signal line 24 may be located between the first electrode plate 25 and the second scan signal line 22, a region where the light emitting signal line 24 is overlapped with the fifth active layer serves as the gate electrode of the fifth transistor T5, and a region where the light emitting signal line 24 is overlapped with the sixth active layer serves as the gate electrode of the sixth transistor T6.

In an exemplary implementation, the light emitting signal line 24 may be provided with a light emitting connection block 24-1. A shape of the light emitting connection block 24-1 may be a block shape (e.g. a rectangle), may be provided on a side of the light emitting signal line 24 away from the first electrode plate 25, and is connected to the light emitting signal line 24, and the light emitting connection block 24-1 is configured to be connected to a light emitting connection electrode formed subsequently.

In an exemplary implementation, the light emitting signal line 24 and the light emitting connection block 24-1 may be of an integral structure connected to each other.

In an exemplary implementation, the first scan signal line 21 and the light emitting signal line 24 may be designed with unequal widths, and widths of the first scan signal line 21 and the light emitting signal line 24 are dimensions in the second direction Y, so that not only a layout of a pixel structure may be facilitated, but also a parasitic capacitance between signal lines may be reduced, which is not limited here in the present disclosure.

In an exemplary implementation, the first scan signal line 21 may include a region overlapping with the first semiconductor layer and a region not overlapping with the first semiconductor layer, and a width of the first scan signal line 21 in the region overlapping with the first semiconductor layer may be greater than a width of the first scan signal line 21 in the region not overlapping with the first semiconductor layer.

In an exemplary implementation, the light emitting signal line 24 may include a region overlapping with the first semiconductor layer and a region not overlapping with the first semiconductor layer, and a width of the first scan signal line 21 in the region overlapping with the first semiconductor layer may be greater than a width of the first scan signal line 21 in the region not overlapping with the first semiconductor layer.

In an exemplary implementation, the first conductive layer may also include a photosensitive shielding electrode 27.

In an exemplary implementation, a shape of the photosensitive shielding electrode 27 may be a strip shape in which a main body portion extends along the second direction Y, may be disposed in the circuit unit of the n-th unit column, and may be located on a side of the seventh active layer 17 in the first direction X. An orthographic projection of the photosensitive shielding electrode 27 on the base substrate is at least partially overlapped with an orthographic projection of a photosensitive region 19-3 of the photosensitive active layer 19 on the base substrate.

In an exemplary implementation, the first conductive layers of the adjacent unit columns (except for the photosensitive shielding electrode 27) may be mirror symmetrical with respect to the centerline. For example, the first conductive layer of the n-th unit column and the first conductive layer of the (n+1)-th unit column may be mirror symmetrical with respect to the centerline.

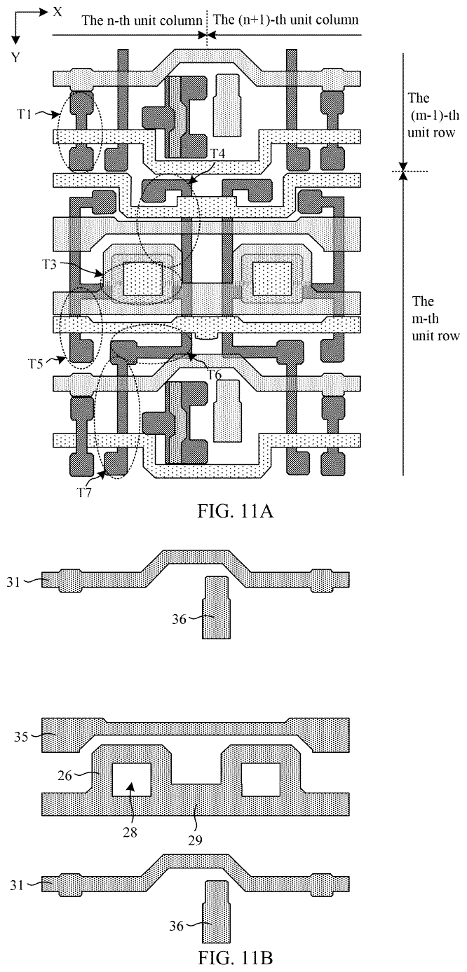

(3) A photosensitive layer of the photosensitive device is formed. In an exemplary implementation, the photosensitive layer forming the photosensitive device may include: performing a conductorization treatment on a base substrate forming the aforementioned pattern by using a pattern of the first conductive layer as a shield, and making the first semiconductor layer not shielded by the first conductive layer be conductive. Herein, the first regions and the second regions of the first transistor T1, the third transistor T3 to the seventh active layer are made to be conductive, and the photosensitive first region 19-1 and the photosensitive second region 19-2 of the photosensitive active layer 19 are made to be conductive, forming the photosensitive first electrode 41 and the photosensitive second electrode 42 of the photosensitive device. The first semiconductor layer shielded by the first conductive layer forms a channel region of the first transistor T1, the third transistor T3 to the seventh transistor T7, and since the photosensitive shielding electrode 27 shields the photosensitive region 19-3, the photosensitive region 19-3 is not to be conductive. Subsequently, a photoresist is coated, and a pattern of the photoresist is formed through a mask, exposure, and development. The pattern of the photoresist exposes the photosensitive shielding electrode 27. First, the photosensitive shielding electrode 27 is etched off through an etching process to expose the photosensitive region 19-3, and then the photosensitive region 19-3 is doped to form a photosensitive layer 43 of the photosensitive device, as shown in FIG. 10.

In an exemplary implementation, the photosensitive device 40 may include a photosensitive first electrode 41, a photosensitive second electrode 42, and a photosensitive layer 43. The photosensitive first electrode 41, the photosensitive layer 43, and the photosensitive second electrode 42 may be arranged along the first direction X, the photosensitive first electrode 41 may be disposed on a side of the photosensitive layer 43 in an opposite direction of the first direction X, and the photosensitive second electrode 42 may be disposed on a side of the photosensitive layer 43 in the first direction X, forming a photodiode with a transverse configuration.

(4) A pattern of a second conductive layer is formed. In an exemplary implementation, forming a pattern of a second conductive layer may include: depositing sequentially a third insulation thin film and a second conductive thin film on the base substrate on which the aforementioned patterns are formed, and the second conductive thin film is patterned through a patterning process to form a third insulation layer that covers the first conductive layer and I-type layer 82, and the pattern of the second conductive layer provided on the third insulation layer, as shown in FIG. 11A and FIG. 11B. FIG. 11B is a planar schematic diagram of the second conductive layer in FIG. 11A. In an exemplary implementation, the second conductive layer may be referred to as a second gate metal (GATE2) layer.

In an exemplary implementation, the pattern of the second conductive layer of each circuit unit at least includes a second electrode plate 26 of the storage capacitor, a first initial signal line 31, and a shielding line 35.

In an exemplary implementation, a profile of second electrode plate 26 may be in a shape of a rectangle, a chamfer may be provided at a corner of the rectangle, an orthographic projection of the second electrode plate 26 on the base substrate is at least overlapped with an orthographic projection of the first electrode plate 25 on the base substrate, the second electrode plate 26 may serve as anther plate of the storage capacitor, and the first electrode plate 25 and the second electrode plate 26 form the storage capacitor of the pixel driving circuit.

In an exemplary implementation, the second electrode plate 26 is provided with an opening 28 which may have a rectangular shape and may be located in the middle of the second electrode plate 26, so that the second electrode plate 26 forms an annular structure. The opening 28 exposes the third insulation layer covering the first electrode plate 25, and an orthographic projection of the first electrode plate 25 on the base substrate contains an orthographic projection of the opening 28 on the base substrate. In an exemplary implementation, the opening 28 is configured to accommodate a tenth via hole to be formed subsequently, and the tenth via hole is located within the opening 28 and exposes the first electrode plate 25, so that a first connection electrode to be formed subsequently is connected to the first electrode plate 25.

In an exemplary implementation, the second electrode plate 26 may be provided with an electrode plate connection stripe 29. A shape of the electrode plate connection strip 29 may be a strip shape extending along the first direction X, and may be provided on a side of the second electrode plate 26 in the first direction X or in an opposite direction of the first direction X. A first end of the electrode plate connection strip 29 is connected to the second electrode plate 26 in the present circuit unit, and a second end of the electrode plate connection strip 29 is connected to the second electrode plate 26 in the adjacent circuit unit in the first direction X, such that the second electrode plates 26 in the adjacent circuit units in one unit row are connected to each other.

In an exemplary implementation, the second electrode plate 26 and the electrode plate connection strip 29 in one unit row may be of an integral structure connected to each other.

In an exemplary implementation, since the second electrode plate 26 in each circuit unit is connected with a first power supply line formed subsequently, second electrode plates 26 in adjacent circuit units are connected with each other to form an integral structure in which the second electrode plates may be used as power supply signal lines as well. This can ensure potential equalization between a plurality of second electrode plates in one unit row, which is beneficial to improving uniformity of a panel and avoiding a poor display of the display substrate, thereby ensuring a display effect of the display substrate.

In an exemplary implementation, a shape of the first initial signal line 31 may be a straight line shape or a polyline shape in which a main body portion extends along the first direction X, the first initial signal line 31 may be located on a side of the second electrode plate 26 in the second direction Y, and the first initial signal line 31 is configured to be connected to a first region of the first active layer through a sixth connection electrode formed subsequently.

In an exemplary implementation, since the first active layer of the present circuit unit is disposed in the previous unit row, in the pixel driving circuit of the present circuit unit, the first region of the first active layer is connected to the first initial signal line 31 of the previous unit row, and the first initial signal line 31 of the present unit row is connected to the first region of the first active layer of the pixel driving circuit in the circuit unit of the next unit row.

In an exemplary embodiment, a shape of the shielding line 35 may be a straight line shape or a polyline shape in which a main body portion extends along the first direction X and may be located between the first scan signal line 21 and the second electrode plate 26, and the shielding line 35 is configured as a shielding layer of the second transistor T2 to shield the channel region of the second transistor T2, so as to ensure the electrical performance of the oxide second transistor T2, and is also configured to serve as a bottom gate electrode of the second transistor T2.

In an exemplary implementation, the pattern of the second conductive layer may also include an eighth bottom gate electrode 36.

In an exemplary implementation, a shape of the eighth bottom gate electrode 36 may be a strip shape extending along the second direction Y. In the first direction X, the eighth bottom gate electrode 36 may be located on a side of the photosensitive device 40 in the first direction X, and in the second direction Y, the eighth bottom gate electrode 36 may be located between the second scan signal line 22 and the first initial signal line 31. In an exemplary implementation, the eighth bottom gate electrode 36 is configured as the bottom gate electrode of the eighth transistor T8, and is configured as a shielding layer of the eighth transistor T8 to shield the channel region of the second transistor T8, so as to ensure an electrical performance of the oxide eighth transistor T8.

In an exemplary implementation, the second conductive layers of the adjacent unit columns (except for the eighth bottom gate electrode 36) may be mirrored symmetrical with respect to the centerline. For example, the second conductive layer of the n-th unit column and the second conductive layer of the (n+1)-th unit column may be mirror symmetrical with respect to the centerline.

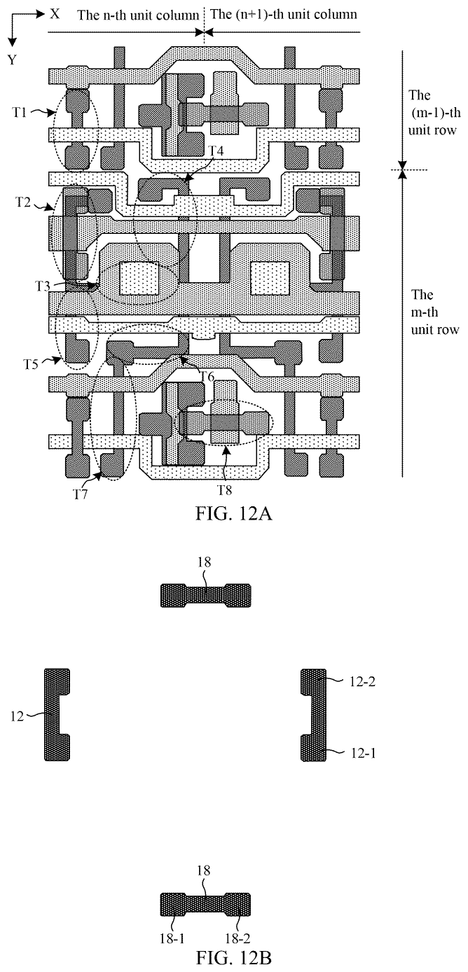

(5) A pattern of a second semiconductor layer is formed. In an exemplary implementation, forming the pattern of the second semiconductor layer may include: depositing a fourth insulation thin film and a second semiconductor thin film sequentially on the base substrate on which the above-mentioned patterns are formed, patterning the second semiconductor thin film through a patterning process to form a fourth insulation layer that covers the base substrate and the pattern of the second semiconductor layer disposed on the fourth insulation layer, as shown in FIG. 12A and FIG. 12B, and FIG. 12B is a schematic plan view of the second conductive layer in FIG. 12A.

In an exemplary implementation, the pattern of the second semiconductor layer of each circuit unit at least includes a second active layer 12 of the second transistor T2.

In an exemplary implementation, a shape of the second active layer 12 may be a strip shape extending along the second direction Y, may be located on a side of the first scan signal line 21 close to the second electrode plate 26, and an orthographic projection of the second active layer 12 on the base substrate is at least partially overlapped with an orthographic projection of the shielding line 35 on the base substrate.

In an exemplary implementation, the second active layer 12 may include a first region, a second region, and a channel region located between the first region and the second region. A first region 12-1 of the second active layer may be located on a side of the shielding line 35 away from the first scan signal line 21, and the second region 12-2 of the second active layer may be located on a side of the shielding line 35 close to the first scan signal line 21.

In an exemplary implementation, the pattern of the second semiconductor layer may also include an eighth active layer 18 of the eighth transistor T8.

In an exemplary implementation, a shape of the eighth active layer 18 may be a strip shape extending along the first direction X, may be located between the second scan signal line 22 and the first initial signal line 31, and an orthographic projection of the eighth active layer 18 on the base substrate is at least partially overlapped with an orthographic projection of the eighth bottom gate electrode 36 on the base substrate.

In an exemplary implementation, the eighth active layer 18 may include a first region, a second region, and a channel region located between the first region and the second region. A first region 18-1 of the eighth active layer 18 may be located on a side of the eighth bottom gate electrode 36 close to the photosensitive device 40, and a second region 18-2 of the eighth active layer 18 may be located on a side of the eighth bottom gate electrode 36 away from the photosensitive device 40.

In an exemplary implementation, second active layers of adjacent unit columns may be mirror symmetrical with respect to a center line. For example, the second active layer of the n-th unit column and the second active layer of the (n+1)-th unit column may be mirror symmetrical with respect to the centerline.

In an exemplary implementation, the second semiconductor layer may be made of an oxide, that is, the second transistor T2 and the eighth transistor T8 are oxide transistors. In an exemplary implementation, the second semiconductor thin film may be made of Indium Gallium Zinc Oxide (IGZO), wherein electron mobility of the Indium Gallium Zinc Oxide (IGZO) is higher than that of amorphous silicon.

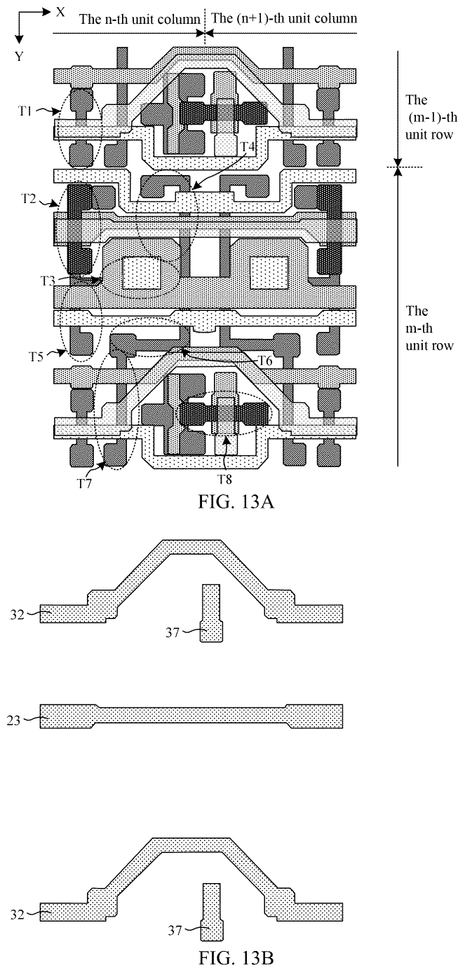

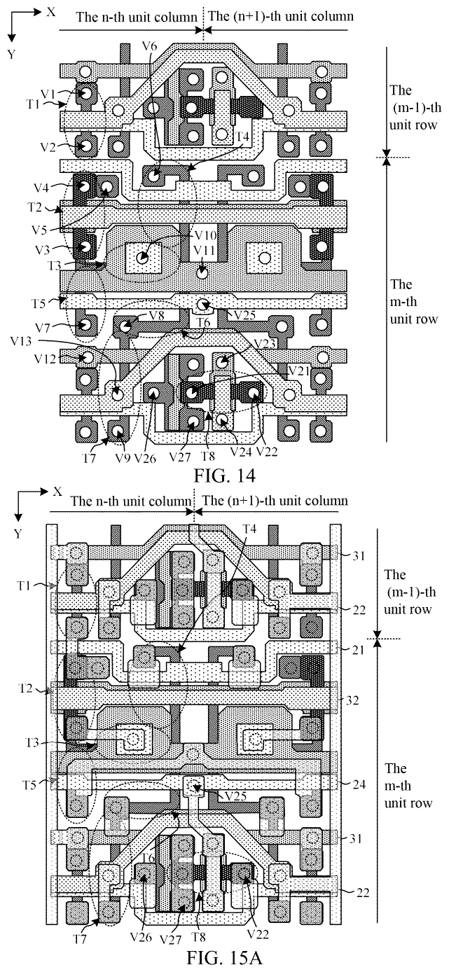

(6) A pattern of a third conductive layer is formed. In an exemplary implementation, forming the pattern of the third conductive layer may include: depositing a fifth insulation thin film and a third conductive thin film sequentially on the base substrate on which the aforementioned patterns are formed, and patterning the third conductive thin film through a patterning process to form a fifth insulation layer covering the second semiconductor layer and the pattern of the third conductive layer disposed on the fifth insulation layer, as shown in FIGS. 13A and 13B, FIG. 13B is a schematic plan view of the third conductive layer in FIG. 13A. In an exemplary implementation, the third conductive layer may be referred to as a third gate metal (GATE3) layer.

In an exemplary implementation, the pattern of the third conductive layer of each circuit unit at least includes a third scan signal line 23 and a second initial signal line 32.

In an exemplary implementation, a shape of the third scan signal line 23 may be a straight line shape or a polyline shape in which a main body portion extends along the first direction X and may be located between the first scan signal line 21 and the second electrode plate 26, and a region where the third scan signal line 23 is overlapped with the second active layer serves as the gate electrode of the second transistor T2.

In an exemplary implementation, an orthographic projection of the third scan signal line 23 on the base substrate is at least partially overlapped with an orthographic projection of the shielding line 35 on the base substrate, and the shielding line 35 and the third scan signal line 23 may be connected to the same signal source, such that the shielding line 35 may serve as the bottom gate electrode of the second transistor T2, and the third scan signal line 23 may serve as the top gate electrode of the second transistor T2, forming a second transistor T2 with a bottom gate and top gate structure.

In an exemplary implementation, a shape of the second initial signal line 32 may be a straight line shape or a polyline shape in which a main body portion extends along the first direction X, and may be located on a side of the light emitting signal line 24 away from the second electrode plate 26, and the second initial signal line 32 is configured to be connected to a first region of the seventh active layer through a seventh connection electrode formed subsequently.

In an exemplary implementation, the pattern of the third conductive layer may also include an eighth top gate electrode 37.

In an exemplary implementation, a shape of the eighth top gate electrode 37 may be a strip shape extending in the second direction Y, and an orthographic projection of the eighth top gate electrode 37 on the base substrate is at least partially overlapped with an orthographic projection of the eighth active layer 18 on the base substrate.

In an exemplary implementation, an orthographic projection of the eighth top gate electrode 37 on the base substrate is at least partially overlapped with an orthographic projection of the eighth bottom gate electrode 36 on the base substrate, the eighth bottom gate electrode 36 is configured to serve as the bottom gate electrode of the eighth transistor T8, and the eighth top gate electrode 37 is configured to serve as the top gate electrode of the eighth transistor T8, forming an eighth transistor T8 with a bottom gate and top gate structure.

In an exemplary implementation, the third scan signal line 23 and the second initial signal line 32 of adjacent unit columns may be mirror symmetrical with respect to the centerline. For example, the third scan signal line 23 and the second initial signal line 32 of the nth unit column and the n+1 unit column may be mirror symmetrical with respect to the centerline.

(7) A pattern of a sixth insulation layer is formed. In an exemplary implementation, forming the pattern of the sixth insulation layer may include: depositing a sixth insulation thin film on the base substrate on which the aforementioned patterns are formed, patterning the fifth insulation thin film using a patterning process to form a sixth insulation layer covering the third conductive layer, wherein a plurality of via holes are provided on the sixth insulation layer, as shown in FIG. 14.

In an exemplary implementation, a plurality of via holes of each circuit unit at least include: a first via hole V1, a second via hole V2, a third via hole V3, a fourth via hole V4, a fifth via hole V5, a sixth via hole V6, a seventh via hole V7, an eighth via hole V8, a ninth via hole V9, a tenth via hole V10, an eleventh via hole V11, a twelfth via hole V12, and a thirteenth via hole V13.

In an exemplary implementation, an orthographic projection of the first via hole V1 on the base substrate is within a range of an orthographic projection of a first region of a first active layer on the base substrate, the sixth insulation layer, the fifth insulation layer, the fourth insulation layer, the third insulation layer and the second insulation layer within the first via hole V1 are etched away to expose a surface of the first region of the first active layer, and the first via hole V1 is configured such that a sixth connection electrode to be formed subsequently is connected with the first region of the first active layer through the first via hole V1.

In an exemplary implementation, an orthographic projection of the second via hole V2 on the base substrate is within a range of an orthographic projection of a second region of the first active layer on the base substrate, the sixth insulation layer, the fifth insulation layer, the fourth insulation layer, the third insulation layer and the second insulation layer within the second via hole V2 are etched away to expose a surface of the second region of the first active layer, and the second via hole V2 is configured such that a second connection electrode to be formed subsequently is connected to the second region of the first active layer through the second via hole V2.

In an exemplary implementation, an orthographic projection of the third via hole V3 on the base substrate is within a range of an orthographic projection of a first region of the second active layer on the base substrate, the sixth insulation layer and the fifth insulation layer within the third via hole V3 are etched away to expose a surface of the first region of the second active layer, and the third via hole V3 is configured such that the first connection electrode to be formed subsequently is connected to the first region of the second active layer through the third via hole V3.

In an exemplary implementation, an orthographic projection of the fourth via hole V4 on the base substrate is within a range of an orthographic projection of a second region of the second active layer on the base substrate, the sixth insulation layer and the fifth insulation layer within the fourth via hole V4 are etched away to expose a surface of the second region of the second active layer, and the fourth via hole V4 is configured such that the second connection electrode to be formed subsequently is connected to the second region of the second active layer through the fourth via hole V4.

In an exemplary implementation, an orthographic projection of the fifth via hole V5 on the base substrate is within a range of an orthographic projection of the first region of the third active layer (also the second region of the fifth active layer) on the base substrate, the sixth insulation layer, the fifth insulation layer, the fourth insulation layer, the third insulation layer and the second insulation layer within the fifth via hole V5 are etched away to expose a surface of the first region of the third active layer (also the second region of the fifth active layer), and the fifth via hole V5 is configured such that a second connection electrode to be formed subsequently is connected to the first region of the third active layer (also the second region of the fifth active layer) through the fifth via hole V5.

In an exemplary implementation, an orthographic projection of the sixth via hole V6 on the base substrate is within a range of an orthographic projection of a first region of the fourth active layer on the base substrate, the sixth insulation layer, the fifth insulation layer, the fourth insulation layer, the third insulation layer and the second insulation layer within the sixth via hole V6 are etched away to expose a surface of the first region of the fourth active layer, and the sixth via hole V6 is configured such that a third connection electrode to be formed subsequently is connected to the first region of the fourth active layer through the sixth via hole V6.

In an exemplary implementation, an orthographic projection of the seventh via hole V7 on the base substrate is within a range of an orthographic projection of a first region of the fifth active layer on the base substrate, the sixth insulation layer, the fifth insulation layer, the fourth insulation layer, the third insulation layer and the second insulation layer within the seventh via hole V7 are etched away to expose a surface of the first region of the fifth active layer, and the seventh via hole V7 is configured such that the fourth connection electrode to be formed subsequently is connected to the first region of the fifth active layer through the seventh via hole V7.

In an exemplary implementation, an orthographic projection of the eighth via hole V8 on the base substrate is within a range of an orthographic projection of the second region of the sixth active layer (also the second region of the seventh active layer) on the base substrate, the sixth insulation layer, the fifth insulation layer, the fourth insulation layer, the third insulation layer and the second insulation layer within the eighth via hole V8 are etched away to expose a surface of the second region of the sixth active layer (also the second region of the seventh active layer), and the eighth via hole V8 is configured such that a fifth connection electrode to be formed subsequently is connected to the second region of the sixth active layer (also the second region of the seventh active layer) through the eighth via hole V8.

In an exemplary implementation, an orthographic projection of the ninth via hole V9 on the base substrate is within a range of an orthographic projection of a first region of the seventh active layer on the base substrate, the sixth insulation layer, the fifth insulation layer, the fourth insulation layer, the third insulation layer and the second insulation layer within the ninth via hole V9 are etched away to expose a surface of the first region of the seventh active layer, and the ninth via hole V9 is configured such that a seventh connection electrode to be formed subsequently is connected to the first region of the seventh active layer through the ninth via hole V9.

In an exemplary implementation, an orthographic projection of the tenth via hole V10 on the base substrate is located within a range of an orthographic projection of the opening 28 on the base substrate, the sixth insulation layer, a fifth insulation layer, a fourth insulation layer and a third insulation layer within the tenth via hole V10 are etched away to expose a surface of the first electrode plate 25, and the tenth via hole V10 is configured such that a first connection electrode to be formed subsequently is connected with the first electrode plate 25 through the tenth via hole V10.

In an exemplary implementation, an orthographic projection of the eleventh via hole V11 on the base substrate is located within a range of an orthographic projection of the electrode plate connection strip 29 on the base substrate, the sixth insulation layer, the fifth insulation layer and the fourth insulation layer within the eleventh via hole V11 are etched off to expose a surface of the electrode plate connection strip 29, and the eleventh via hole V11 is configured such that a fourth connection electrode to be formed subsequent is connected to the electrode plate connection strip 29 through the eleventh via hole V11. In an exemplary implementation, the eleventh via hole V11 may be disposed between two adjacent circuit units, and the adjacent two circuit units may share the same eleventh via hole V11.

In an exemplary implementation, an orthographic projection of the twelfth via hole V12 on the base substrate is within a range of an orthographic projection of the first initial signal line 31 on the base substrate, the sixth insulation layer, the fifth insulation layer, and the fourth insulation layer within the twelfth via hole V12 are etched off to expose a surface of the first initial signal line 31, and the twelfth via hole V12 is configured such that a sixth connection electrode to be formed subsequent is connected to the first initial signal line 31 through the twelfth via hole V12.

In an exemplary implementation, an orthographic projection of the thirteenth via hole V13 on the base substrate is within a range of an orthographic projection of the second initial signal line 32 on the base substrate, the sixth insulation layer, the fifth insulation layer, and the fourth insulation layer within the thirteenth via hole V13 are etched off to expose a surface of the second initial signal line 32, and the thirteenth via hole V13 is configured such that a seventh connection electrode to be formed subsequent is connected to the second initial signal line 32 through the thirteenth via hole V13.

In an exemplary implementation, the sixth insulation layer may also include a twenty-first via hole V21, a twenty-second via hole V22, a twenty-third via hole V23, a twenty-fourth via hole V24, a twenty-fifth via hole V25, a twenty-sixth via hole V26, and a twenty-seventh via hole V27.

In an exemplary implementation, an orthographic projection of the twenty-first via hole V21 on the base substrate is within a range of an orthographic projection of a first region of the second active layer on the base substrate, the sixth insulation layer and the fifth insulation layer within the twenty-first via hole V21 are etched away to expose a surface of the first region of the eighth active layer, and the twenty-first via hole V21 is configured such that a twelfth connection electrode to be formed subsequently is connected with the first region of the eighth active layer through the twenty-first via hole V21.

In an exemplary implementation, an orthographic projection of the twenty-second via hole V22 on the base substrate is within a range of an orthographic projection of the second region of the eighth active layer on the base substrate, the sixth insulation layer and the fifth insulation layer within the twenty-second via hole V22 are etched away to expose a surface of the second region of the eighth active layer, and the twenty-second via hole V22 is configured such that a thirteenth connection electrode to be formed subsequently is connected to the second region of the eighth active layer through the twenty-second via hole V22.

In an exemplary implementation, an orthographic projection of the twenty-third via hole V23 on the base substrate is within a range of an orthographic projection of the eighth bottom gate electrode 36 on the base substrate, the sixth insulation layer, the fifth insulation layer, and the fourth insulation layer within the twenty-third via hole V23 are etched off to expose a surface of the eighth bottom gate electrode 36, and the twenty-third via hole V23 is configured such that a light emitting connection electrode to be formed subsequently is connected to the eighth bottom gate electrode 36 through the twenty-third via hole V23.

In an exemplary implementation, an orthographic projection of the twenty-fourth via 24 on the base substrate is within a range of an orthographic projection of the eighth top gate electrode 37, the sixth insulation layer in the twenty-fourth via hole V24 is etched away to expose a surface of the eighth top gate electrode 37, and the twenty-fourth via hole V24 is configured such that a light emitting connection electrode to be formed subsequently is connected to the eighth top gate electrode 37 through the twenty-fourth via hole V24.

In an exemplary implementation, an orthographic projection of the twenty-fifth via hole V25 on the base substrate is within a range of an orthographic projection of the light emitting connection block 24-1 of the light emitting signal line 24 on the base substrate, the sixth insulation layer, the fifth insulation layer, the fourth insulation layer and the third insulation layer within the twenty-fifth via hole V25 are etched off to expose a surface of the light emitting connection block 24-1, and the twenty-fifth via hole V25 is configured such that a light emitting connection electrode formed subsequently is connected to the light emitting connection block 24-1 through the twenty-fifth via hole V25.

In an exemplary implementation, an orthographic projection of the twenty-sixth via hole V26 on the base substrate is within a range of an orthographic projection of the photosensitive first electrode 41 of the photosensitive device 40 on the base substrate, the sixth insulation layer, the fifth insulation layer, the fourth insulation layer, the third insulation layer, and the second insulation layer within the twenty-sixth via hole V26 are etched off to expose a surface of the photosensitive first electrode 41, and the twenty-sixth via hole V26 is configured such that an eleventh connection electrode to be formed subsequently is connected to the photosensitive first electrode 41 through the photosensitive first electrode 41.

In an exemplary implementation, an orthographic projection of the twenty-seventh via hole V27 on the base substrate is within a range of an orthographic projection of the photosensitive second electrode 42 of the photosensitive device 40 on the base substrate, the sixth insulation layer, the fifth insulation layer, the fourth insulation layer, the third insulation layer and the second insulation layer within the twenty-seventh via hole V27 are etched off to expose a surface of the photosensitive second electrode 42, and the twenty-seventh via hole V27 is configured such that a twelfth connection electrode to be formed subsequently is connected to the photosensitive second electrode 42 through the twenty-seventh via hole V27.

In an exemplary implementation, the first via holes V1 to the thirteenth via holes V13 of adjacent unit columns may be mirror symmetrical with respect to a centerline. For example, the first via hole V1 to the thirteenth via hole V13 of the n-th unit row and the first via hole V1 to the thirteenth via hole V13 of the (n+1)-th unit row may be mirror symmetrical with respect to the centerline.

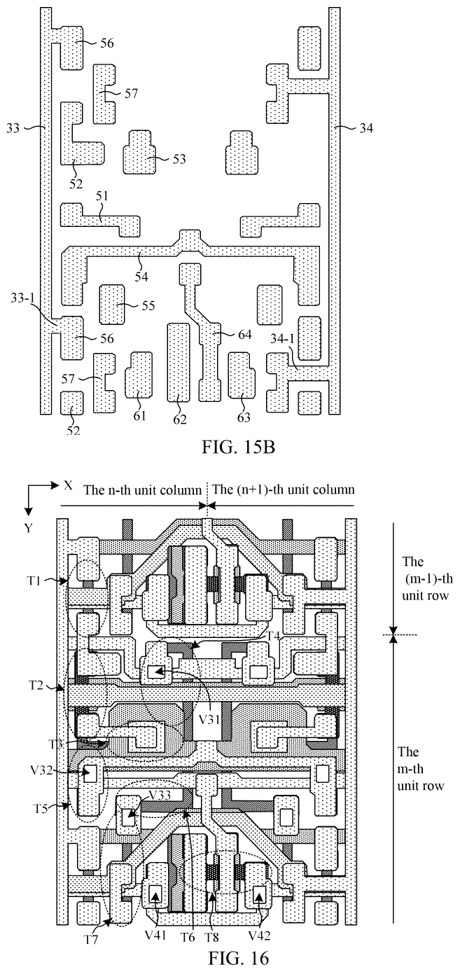

(8) A pattern of a fourth conductive layer is formed. In an exemplary implementation, forming the pattern of the fourth conductive layer may include: depositing a fourth conductive thin film on the base substrate on which the aforementioned patterns are formed, and patterning the fourth conductive thin film through a patterning process to form the fourth conductive layer disposed on the sixth insulation layer, as shown in FIG. 15A and FIG. 15B, and FIG. 15B is a schematic plan view of the fourth conductive layer in FIG. 15A. In an exemplary implementation, the fourth conductive layer may be referred to as a first source drain metal (SD1) layer.

In an exemplary implementation, the fourth conductive layer of each circuit unit at least includes a first connection electrode 51, a second connection electrode 52, a third connection electrode 53, a fourth connection electrode 54, a fifth connection electrode 55, a sixth connection electrode 56, and a seventh connection electrode 57.

In an exemplary implementation, a shape of the first connection electrode 51 may be a strip shape in which a main body portion extends along the first direction X, a first end of the first connection electrode 51 is connected with the first region of the second active layer through the third via hole V3, and a second end of the first connection electrode 51 is connected with the first electrode plate 25 through the tenth via hole V10. In an exemplary implementation, since the first electrode plate 25 serves as the gate electrode of the third transistor T3, the first connection electrode 51 enables the first electrode of the second transistor T2, the gate electrode of the third transistor T3 and the first electrode plate 25 of the storage capacitor to have a same potential to serve as a first node N1 of the pixel driving circuit.

In an exemplary implementation, a shape of the second connection electrode 52 may be an “L” shape, a first end of the second connection electrode 52 is connected to the second region of the first active layer through the second via hole V2, a second end of the second connection electrode 52 is connected to the first region of the third active layer (also the second region of the fifth active layer) through the fifth via hole V5, and the second region of the second active layer is connected between the first and second ends of the second connection electrode 52 through the fourth via hole V4. In an exemplary implementation, the second connection electrode 52 enables the second electrode of the first transistor T1, the second electrode of the second transistor T2, the first electrode of the third transistor T3, and the second electrode of the fifth transistor T5 to have the same potential to serve as the second node N2 of the pixel driving circuit.

In an exemplary implementation, a shape of the third connection electrode 53 may be a block shape (such as a rectangle), and the third connection electrode 53 is connected to the first region of the fourth active layer through the sixth via hole V6. In an exemplary implementation, the third connection electrode 53 may serve as a first electrode of the fourth transistor T4, and the third connection electrode 53 is configured to be connected with a twenty-first connection electrode formed subsequently.

In an exemplary implementation, a shape of the fourth connection electrode 54 may be an “L” shape, a first end of the fourth connection electrode 54 is connected to the first region of the fifth active layer through the seventh via hole V7, a second end of the fourth connection electrode 54 is connected to the electrode plate connection strip 29 through the eleventh via hole V11, and the fourth connection electrode 54 is configured to be connected with a twenty-second connection electrode formed subsequently. In an exemplary implementation, since the electrode plate connection strip 29 is connected to the second electrode plate 26, the fourth connection electrode 54 achieves that the first electrode of the fifth transistor T5 in the circuit unit and the second electrode 26 of the storage capacitor have the same potential.

In an exemplary implementation, in at least one unit row, a fourth connection electrode 54 in the N-th column and a fourth connection electrode 54 in the (N+1)-th column may be of an integral structure connected to each other. In an exemplary implementation, since the fourth connection electrode 54 in each circuit unit is connected with the first power supply line formed subsequently, the fourth connection electrodes 54 of adjacent circuit units are formed into an integral structure in which they are connected with each other, the fourth connection electrodes 54 of adjacent circuit units can be guaranteed to have a same potential, therefore, the first electrodes of the fifth transistors T5 in the adjacent circuit units have a same potential, and the second electrode plates 26 of the storage capacitor in the adjacent circuit units have a same potential, which is beneficial for improving the uniformity of the panel, avoiding poor display of the display substrate and ensuring the display effect of the display substrate.

In an exemplary implementation, a shape of the fifth connection electrode 55 may be a block shape (such as a rectangle), and the fifth connection electrode 55 is connected with the second region of the sixth active layer (which is also the second region of the seventh active layer) through the eighth via hole V8. In an exemplary implementation, the fifth connection electrode 55 may serve as a second electrode of the sixth transistor T6 and a second electrode of the seventh transistor T7 simultaneously, and the sixth connection electrode 56 is configured to be connected with a twenty-third connection electrode formed subsequently.

In an exemplary implementation, a shape of the sixth connection electrode 56 may be a strip shape extending along the second direction Y, a first end of the sixth connection electrode 56 is connected to the first region of the first active layer through the first via hole V1, and a second end of the sixth connection electrode 56 is connected to the first initial signal line 31 through the twelfth via hole V12, such that the first initial signal transmitted by the first initial signal line 31 is written to the first electrode of the first transistor T1.

In an exemplary implementation, since the first active layer of the present circuit unit is disposed in the previous unit row, in the pixel driving circuit of the present circuit unit, the first region of the first active layer is connected to the first initial signal line 31 of the previous unit row, and the first initial signal line 31 of the present unit row is connected to the first region of the first active layer of the pixel driving circuit in the circuit unit of the next unit row.

In an exemplary implementation, a shape of the seventh connection electrode 57 may be a strip shape extending along the second direction Y, a first end of the seventh connection electrode 57 is connected to the first region of the seventh active layer through the ninth via hole V9, and a second end of the seventh connection electrode 57 is connected to the second initial signal line 32 through the thirteenth via hole V13, such that the initial signal transmitted by the second initial signal line 32 is written to the first electrode of the seventh transistor T7.

In an exemplary implementation, the fourth conductive layer may also include a first initial connection line 33, a first initial connection block 33-1, a second initial connection line 34, and a second initial connection block 34-1.

In an exemplary implementation, a shape of the first initial connection line 33 may be a straight line shape or a polyline shape in which a main body portion extends along the second direction Y, and may be disposed in the n-th unit column. A shape of the first initial connection block 33-1 may be a strip shape in which a main body portion extends along the first direction X, a first end of the first initial connection block 33-1 is connected to the first initial connection line 33, and a second end of the first initial connection block 33-1 is connected to the sixth connection electrode 56. Since the sixth connection electrode 56 is connected to the first initial signal line 31 through a via hole, the first initial signal line 31 in which a main body portion extends along the first direction X and the first initial connection line 33 in which a main body portion extends along the second direction Y are connected to each other, forming a network communication structure for transmitting the first initial signal on the display substrate, which may minimize a resistance of the first initial signal line, reduce a voltage drop of the first initial signal, effectively improving the uniformity of the first initial signal in the display substrate, effectively improving the uniformity of the display, and improving the display quality and display quality.

In an exemplary implementation, in the at least one circuit unit, the first initial connection line 33, the first initial connection block 33-1, and the sixth connection electrode 56 may be of an integral structure connected to each other.

In an exemplary implementation, a shape of the second initial connection line 34 may be a straight line shape or a polyline shape in which a main body portion extends along the second direction Y, and may be disposed in the (n+1)-th unit column. A shape of the second initial connection block 34-1 may be a strip shape in which a main body portion extends along the first direction X, a first end of the second initial connection block 34-1 is connected to the second initial connection line 34, and a second end of the second initial connection block 34-1 is connected to the seventh connection electrode 57. Since the seventh connection electrode 57 is connected to the second initial signal line 32 through a via hole, the second initial signal line 32 in which a main body portion extends along the first direction X and the second initial connection line 34 in which a main body portion extends along the second direction Y are connected to each other, forming a network communication structure for transmitting the second initial signal on the display substrate, which may minimize a resistance of the second initial signal line, reduce a voltage drop of the second initial signal, effectively improving the uniformity of the second initial signal in the display substrate, effectively improving display uniformity, and improving the display attribute and display quality.

In an exemplary implementation, in the at least one circuit unit, the second initial connection line 34, the second initial connection block 34-1, and the seventh connection electrode 57 may be of an integral structure connected to each other.

In an exemplary implementation, only one of the first initial connection lines 33 and the second initial connection lines 34 may be disposed in one unit column, and in the first direction X, the first initial connection lines 33 and the second initial connection lines 34 are alternately disposed. For example, the first initial connection lines 33 may be disposed in the n-th unit column and the (n+2)-th unit column, and the second initial connection lines 34 may be disposed in the (n+1)-th unit column and the (n+3)-th unit column.

In an exemplary implementation, the first initial connection lines 33 of adjacent unit columns may be of an integral structure connected to each other, or the adjacent unit columns may share the same first initial connection line 33. For example, the (n−1)-th unit column and the n-th unit column may share the same first initial connection line 33.

In an exemplary implementation, the second initial connection lines 34 of adjacent unit columns may be of an integral structure connected to each other, or the adjacent unit columns may share the same second initial connection line 34. For example, the (n+1)-th unit column and the (n+2)-th unit column may share the same second initial connection line 34.

In an exemplary implementation, the fourth conductive layer may also include an eleventh connection electrode 61, a twelfth connection electrode 62, a thirteenth connection electrode 63, and a light emitting connection electrode 64.

In an exemplary implementation, a shape of the eleventh connection electrode 61 may be a block shape (e.g., a rectangle), the eleventh connection electrode 61 is connected to the photosensitive first electrode 41 through the twenty-sixth via hole V26, and the eleventh connection electrode 61 is configured to be connected to a thirty-first connection electrode formed subsequently.

In an exemplary implementation, a shape of the twelfth connection electrode 62 may be a strip shape extending along the second direction Y, a middle portion of the twelfth connection electrode 62 is connected to the first region of the eighth active layer through the twenty-first via hole V21, and both ends of the twelfth connection electrode 62 are connected to the photosensitive second electrode 42 through the twenty-seventh via hole V27. In an exemplary implementation, the twelfth connection electrode 62 achieves a connection between the first electrode of the eighth transistor T8 and the photosensitive second electrode 42 of the photosensitive device.

In an exemplary implementation, a shape of the thirteenth connection electrode 63 may be a shape block (e.g., a rectangle), the thirteenth connection electrode 63 is connected to the second region of the eighth active layer through the twenty-second via hole V22, and the thirteenth connection electrode 63 is configured to be connected to a thirty-second connection electrode formed subsequently.

In an exemplary implementation, a shape of the light emitting connection electrode 64 may be a strip shape extending along the second direction Y, a first end of the light emitting connection electrode 64 is connected to the light emitting connection block 24-1 through the twenty-fifth via hole V25, a second end of the light emitting connection electrode 64 is connected to the eighth top gate electrode 37 through the twenty-fourth via hole V24, and a position between the first end and the second end of the light emitting connection electrode 64 is connected to the eighth bottom gate electrode 36 through the twenty-third via hole V23. In an exemplary implementation, since the light emitting connection block 24-1 is connected to the light emitting signal line 24, it is achieved that the light emitting signal line 24 may control the eighth transistor T8 to be turned on and off.

In an exemplary implementation, the first connection electrodes 51 to the seventh connection electrodes 57 of adjacent unit columns may be mirror symmetrical with respect to the centerline.

(9) A pattern of a first planarization layer is formed. In an exemplary implementation, forming the pattern of the first planarization layer may include: coating a first planarization thin film on the base substrate on which the aforementioned patterns are formed, patterning the first planarization thin film using a patterning process to form a first planarization layer covering the pattern of the fourth conductive layer, wherein the first planarization layer is provided with a plurality of via holes, as shown in FIG. 16.

In an exemplary implementation, a plurality of via holes in each circuit unit at least includes a thirty-first via hole V31, a thirty-second via hole V32, and a thirty-third via hole V33.

In an exemplary implementation, an orthographic projection of the thirty-first via hole V31 on the base substrate is within a range of an orthographic projection of the third connection electrode 53 on the base substrate, the first planarization layer within the thirty-first via hole V31 is etched away to expose a surface of the third connection electrode 53, and the thirty-first via hole V31 is configured such that an twenty-first connection electrode formed subsequently is connected with the third connection electrode 53 through the thirty-first via hole V31.

In an exemplary implementation, an orthographic projection of the thirty-second via hole V32 on the base substrate is within a range of an orthographic projection of the fourth connection electrode 54 on the base substrate, the first planarization layer in the thirty-second via hole V32 is etched away to expose a surface of the fourth connection electrode 54, and the thirty-second via hole V32 is configured such that a twenty-second connection electrode to be formed subsequently is connected to the fourth connection electrode 54 through the thirty-second via hole V32.

In an exemplary implementation, an orthographic projection of the thirty-third via hole V33 on the base substrate is within a range of an orthographic projection of the fifth connection electrode 55 on the base substrate, the first planarization layer in the thirty-third via hole V33 is etched away to expose a surface of the fifth connection electrode 55, and the thirty-third via hole V33 is configured such that a twenty-third connection electrode to be formed subsequently is connected to the fifth connection electrode 55 through the thirty-third via hole V33.

In an exemplary implementation, the first planarization layer may also include a forty-first via hole V41 and a forty-second via hole V42.

In an exemplary implementation, an orthographic projection of the forty-first via hole V41 on the base substrate is within a range of an orthographic projection of the eleventh connection electrode 61 on the base substrate, the first planarization layer within the forty-first via hole V41 is etched away to expose a surface of the eleventh connection electrode 61, and the forty-first via hole V41 is configured such that a thirty-first connection electrode formed subsequently is connected with the eleventh connection electrode 61 through the forty-first via hole V41.

In an exemplary implementation, an orthographic projection of the forty-second via hole V42 on the base substrate is within a range of an orthographic projection of the thirteenth connection electrode 63 on the base substrate, the first planarization layer within the forty-second via hole V42 is etched away to expose a surface of the thirteenth connection electrode 63, and the forty-second via hole V42 is configured such that a thirty-second connection electrode to be formed subsequently is connected with the thirteenth connection electrode 63 through the forty-second via hole V42.

In an exemplary implementation, the thirty-first via holes V31 to the thirty-third via holes V33 on the first planarization layer of the adjacent unit columns may be mirror symmetrical with respect to the centerline.

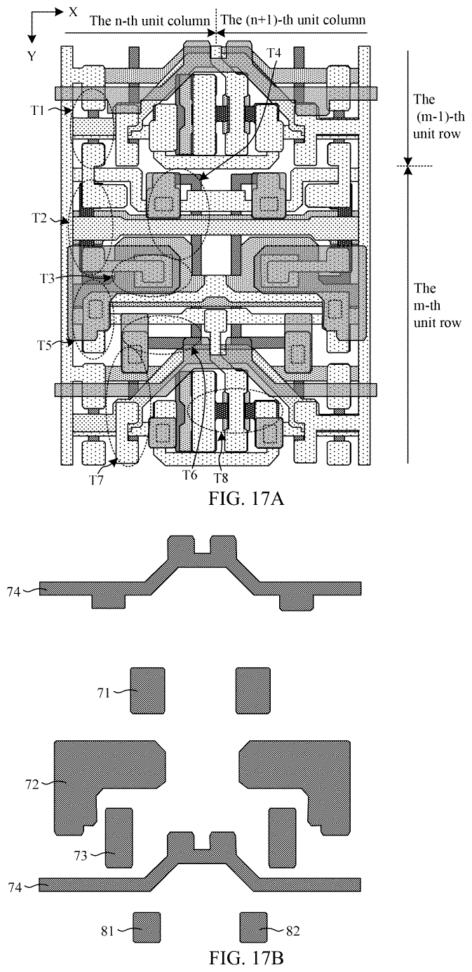

(10) A pattern of a fifth conductive layer is formed. In an exemplary implementation, forming the pattern of the fifth conductive layer may include: depositing a fifth conductive thin film on the base substrate on which the above-mentioned patterns are formed, and patterning the fifth conductive thin film using a patterning process to form the fifth conductive layer disposed on the first planarization layer, as shown in FIG. 17A and FIG. 17B, and FIG. 17B is a schematic plan view of the fifth conductive layer in FIG. 17A. In an exemplary implementation, the fifth conductive layer may be referred to as a second source-drain metal (SD2) layer.

In an exemplary implementation, the fifth conductive layer of each circuit unit at least includes a twenty-first connection electrode 71, a twenty-second connection electrode 72, a twenty-third connection electrode 73, and a sensing power supply connection line 74.

In an exemplary implementation, a shape of the twenty-first connection electrode 71 may be a block shape (for example, a rectangle), and the twenty-first connection electrode 71 is connected with the third connection electrode 53 through the thirty-first via hole V31 and is configured to be connected with a data signal line to be formed subsequently.

In an exemplary implementation, a shape of the twenty-second connection electrode 72 may be an “L” shape, and the twenty-second connection electrode 72 may be connected with the fourth connection electrode 54 through the thirty-second via hole V32 and is configured to be connected with a first power supply line to be formed subsequently.

In an exemplary implementation, the twenty-second connection electrode 72 may also serve as a shielding electrode, an orthographic projection of the twenty-second connection electrode 72 on the base substrate is at least partially overlapped with an orthographic projection of the first connection electrode 51 on the base substrate, and the orthographic projection of the twenty-second connection electrode 72 on the base substrate is at least partially overlapped with orthographic projections of the second region of the first active layer and the first region of the second active layer on the base substrate. In an exemplary implementation, the twenty-second connection electrode 72 may block light emitted from the light emitting device and reflected light from the film layer from irradiating oxide transistors, and may prevent characteristic drift of the oxide transistors due to light illumination, thereby improving the electrical characteristics of the oxide transistors. Since the twenty-second connection electrode 72 is connected to a first power supply line to be formed subsequently, the twenty-second connection electrode having a constant potential may effectively shield the first node N1 in the pixel driving circuit from being affected by data voltage jumps and other signals, thereby preventing data voltage jumps and other signals from affecting the potential of the first node N1, and effectively avoiding the deterioration of Cross Talk.

In an exemplary implementation, the twenty-second connection electrodes 72 of the adjacent circuit unit columns in the first direction X may be of an integral structure connected to each other. For example, the twenty-second connection electrodes 72 of the (n−1)-th unit column and the n-th unit column may be of an integral structure connected to each other. As a further example, the twenty-second connection electrodes 72 of the (n+1)-th unit column and the (n+2)-th unit column may be of an integral structure connected to each other.

In an exemplary implementation, a shape of the twenty-third connection electrode 73 may be a strip shape in which a main body portion extends along the second direction Y, the twenty-third connection electrode 73 is connected to the fifth connection electrode 55 through the thirty-third via hole V33 and is configured to be connected to an anode connection electrode to be formed subsequently.

In an exemplary implementation, a shape of the sensing power supply connection line 74 may be a straight line shape or a polyline shape in which a main body portion extends along the first direction X, and the sensing power supply connection line 74 may be located on a side of the light emitting signal line 24 away from the second electrode plate 26, and is configured to be connected to a sensing power supply line to be formed subsequently.

In an exemplary implementation, the fifth conductive layer may also include a thirty-first connection electrode 81 and a thirty-second connection electrode 82.

In an exemplary implementation, a shape of the thirty-first connection electrode 81 may be a block shape (such as a rectangle), and the thirty-first connection electrode 81 may be disposed in the circuit unit of the n-th unit column and is connected to the eleventh connection electrode 61 through the forty-first via hole V41. The thirty-first connection electrode 81 is configured to be connected to a sensing power supply line to be formed subsequently.

In an exemplary implementation, a shape of the thirty-second connection electrode 82 may be a block shape (e.g., a rectangle), and the thirty-second connection electrode 82 may be disposed in the circuit unit of the (n+1)-th unit column and is connected to the thirteenth connection electrode 63 through the forty-second via hole V42. The thirty-second connection electrode 82 is configured to be connected to a sensing signal line to be formed subsequently.

In an exemplary implementation, the twenty-first connection electrodes 71 to twenty-third connection electrodes 73 and the sensing power supply connection lines 74 of adjacent unit columns may be mirror symmetrical with respect to the centerline.

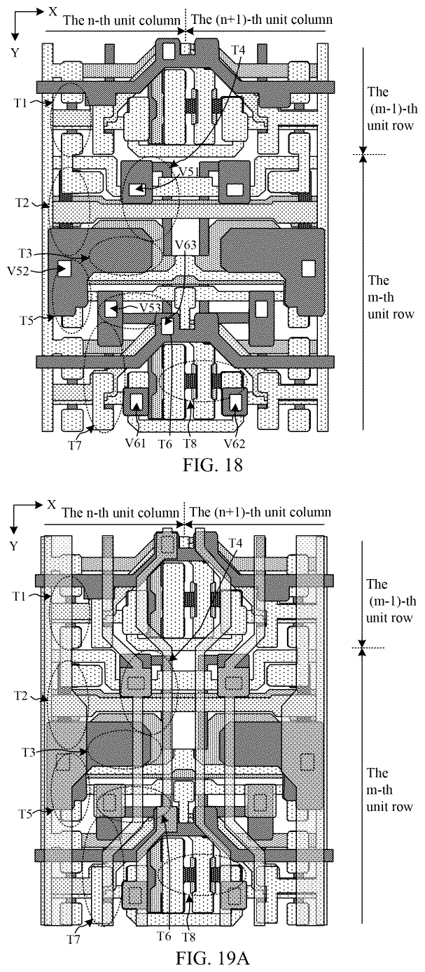

(11) A pattern of a second planarization layer is formed. In an exemplary implementation, forming the pattern of the second planarization layer may include coating a second planarization thin film on the base substrate on which the aforementioned patterns are formed, patterning the second planarization thin film using a patterning process to form the second planarization layer covering a pattern of the fifth conductive layer, a plurality of via holes are provided on the second planarization layer, as shown in FIG. 18.

In an exemplary implementation, the plurality of via holes in each circuit unit at least includes a fifty-first via hole V51, a fifty-second via hole V52, and a fifty-third via hole V53.

In an exemplary implementation, an orthographic projection of the fifty-first via hole V51 on the base substrate is within a range of an orthographic projection of the twenty-first connection electrode 71 on the base substrate, the second planarization layer within the fifty-first via hole V51 is etched away to expose a surface of the twenty-first connection electrode 71, and the fifty-first via hole V51 is configured such that a data signal line to be formed subsequently is connected with the twenty-first connection electrode 71 through the fifty-first via hole V51.

In an exemplary implementation, an orthographic projection of the fifty-second via hole V52 on the base substrate is within a range of an orthographic projection of the twenty-second connection electrode 72 on the base substrate, the second planarization layer within the fifty-second via hole V52 is etched away to expose a surface of the twenty-second connection electrode 72, and the fifty-second via hole V52 is configured such that a first power supply line to be formed subsequently is connected with the twenty-second connection electrode 72 through the fifty-second via hole V52.

In an exemplary implementation, an orthographic projection of the fifty-third via hole V53 on the base substrate is within a range of an orthographic projection of the twenty-third connection electrode 73 on the base substrate, the second planarization layer within the fifty-third via hole V53 is etched away to expose a surface of the twenty-third connection electrode 73, and the fifty-third via hole V53 is configured such that the anode connection electrode to be formed subsequently is connected to the twenty-third connection electrode 73 through the fifty-third via hole V53.

In an exemplary implementation, the second planarization layer may also include a sixty-first via hole V61, a sixty-second via hole V62, and a sixty-third via hole V63.

In an exemplary implementation, an orthographic projection of the sixty-first via hole V61 on the base substrate is within a range of the orthographic projection of the thirty-first connection electrode 81 on the base substrate, the second planarization layer within the sixty-first via hole V61 is etched away to expose a surface of the thirty-first connection electrode 81, and the sixty-first via hole V61 is configured such that a sensing power supply line to be formed subsequently is connected to the thirty-first connection electrode 81 through the sixty-first via hole V61.

In an exemplary implementation, an orthographic projection of the sixty-second via hole V62 on the base substrate is within a range of an orthographic projection of the thirty-second connection electrode 82 on the base substrate, the second planarization layer within the sixty-second via hole V62 is etched away to expose a surface of the thirty-second connection electrode 82, and the sixty-second via hole V62 is configured such that a sensing signal line to be formed subsequently is connected with the thirty-second connection electrode 82 through the sixty-second via hole V62.

In an exemplary implementation, an orthographic projection of the sixty-third via hole V63 on the base substrate is within a range of an orthographic projection of the sensing power supply connection line 74 on the base substrate, the second planarization layer within the sixty-third via hole V63 is etched off to expose a surface of the sensing power supply connection line 74, and the sixty-third via hole V63 is configured such that a sensing power supply line to be formed subsequently is connected to the sensing power supply connection line 74 through the sixty-third via hole V63.

In an exemplary implementation, the fifty-first via holes V51 to the fifty-third via holes V53 of adjacent unit columns may be mirror symmetrical with respect to the centerline.

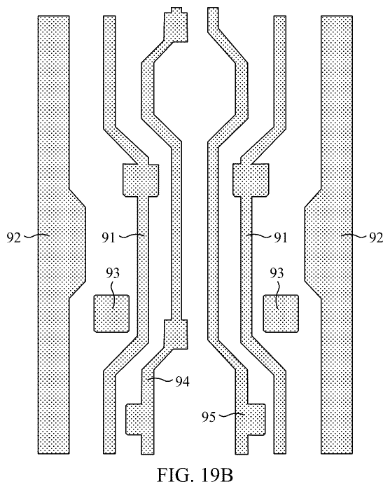

(12) A pattern of a sixth conductive layer is formed. In an exemplary implementation, forming a sixth conductive layer may include: depositing a sixth conductive thin film on the base substrate on which the aforementioned patterns are formed, patterning the sixth conductive thin film using a patterning process to form a sixth conductive layer disposed on the second planarization layer, as shown in FIG. 19A and FIG. 19B, and FIG. 19B is a schematic plan view of the sixth conductive layer in FIG. 19A. In an exemplary implementation, the sixth conductive layer may be referred to as a third source-drain metal (SD3) layer.

In an exemplary implementation, a sixth conductive layer of each circuit unit at least includes a data signal line 91, a first power supply line 92, and an anode connection electrode 93.

In the exemplary implementation, the data signal line 91 may be a straight line shape or a polyline shape in which a main body portion extends along the second direction Y, and the data signal line 91 is connected to the twenty-first connection electrode 71 through the fifty-first via hole V51. Since the twenty-first connection electrode 71 is connected with the third connection electrode 53 through a via hole and the third connection electrode 53 is connected with the first region of the fourth active layer through a via hole, a connection between the data signal line 91 and the first electrode of the fourth transistor T4 is achieved, and the data signal line 91 may write a data signal into the first electrode of the fourth transistor T4.

In an exemplary implementation, since the data signal line is disposed in the third source-drain metal (SD3) layer and the first planarization layer and the second planarization layer which are relatively thick are spaced between the data signal line and a corresponding signal line, a distance between the data signal line and the corresponding signal line is increased, and a parasitic capacitance between the data signal line and the corresponding signal line is reduced, thereby effectively reducing a capacitive load of the data signal line.

In an exemplary implementation, a shape of the first power supply line 92 may be a straight line shape or a polyline shape in which a main body portion extends along the second direction Y, and the first power supply line 92 is connected to the twenty-second connection electrode 72 through the fifty-second via hole V52. Since the twenty-second connection electrode 72 is connected to the fourth connection electrode 54 through a via hole, and the fourth connection electrode 54 is connected to the first region of the fifth active layer and the second electrode plate 26 through a via hole, a connection of the first power supply line 92 to the first electrode of the fifth transistor T5 and the second electrode plate 26 is achieved, and the first power supply line 92 may write the first power supply signal to the first electrode of the fifth transistor T5 and the second electrode plate 26 of the storage capacitor.

In an exemplary implementation, the first power supply line 92 may be of a polyline with unequal widths, which may not only facilitate a layout of a pixel structure, but also reduce a parasitic capacitance between the first power supply line and a data signal line.

In an exemplary implementation, the first power supply lines 92 of the adjacent circuit unit columns in the first direction X may be of an integral structure connected to each other, or the adjacent unit columns may share the same first power supply line 92, for example, the first power supply lines 92 of the (n−1)-th unit column and the n-th unit column may be of an integral structure connected to each other. As another example, the first power supply lines 92 of the (n+1)-th unit column and the (n+2)-th unit column may be of an integral structure connected to each other.

In an exemplary implementation, a shape of the anode connection electrode 93 may be a block shape (e.g., a rectangle), the anode connection electrode 93 is connected to the twenty-third connection electrode 73 through the fifty-third via hole V53, and the anode connection electrode 93 is configured to be connected to an anode to be formed subsequently. Since the twenty-third connection electrode 73 is connected with the fifth connection electrode 55 through a via hole, and the fifth connection electrode 55 is connected with the second region of the sixth active layer and the second region of the seventh active layer through a via hole, a connection of the anode formed subsequently, to the second electrode of the sixth transistor T6 and the second electrode of the seventh transistor T7 may be achieved, and the pixel driving circuit may drive a light emitting device to emit light.

In an exemplary implementation, the sixth conductive layer may also include a sensing power supply line 94 and a sensing signal line 95.

In an exemplary implementation, the sensing power supply line 94 may be disposed in the circuit unit of the n-th unit column, a shape of the sensing power supply line 94 may be a straight line shape or a polyline shape in which a main body portion extends along the second direction Y, and the sensing power supply line 94 is connected to the thirty-first connection electrode 81 through the sixty-first via hole V61. Since the thirty-first connection electrode 81 is connected to the eleventh connection electrode 61 through a via hole, and the eleventh connection electrode 61 is connected to the photosensitive first electrode 41 through a via hole, a connection of the sensing power supply line 94 to the photosensitive first electrode 41 of the photosensitive device is achieved.

In an exemplary implementation, the sensing power supply line 94 is also connected to the sensing power supply connection line 74 through the sixty-third via hole V63, such that the sensing power supply connection line 74 in which a main body portion extends along the first direction X and the sensing power supply line 94 in which a main body portion extends along the second direction Y are connected to each other, forming a sensing power supply line of a network communication structure on the display substrate, which not only minimizes a resistance of the sensing power supply line, reduces a voltage drop of the photosensitive power supply signal, but also effectively improves the uniformity of the photosensitive power supply signal in the display substrate, and effectively improves the photosensitive uniformity of the photosensitive device.

In an exemplary implementation, the sensing signal line 95 may be disposed in the circuit unit of the (n+1)-th unit column, a shape of the sensing signal line 95 may be a straight line shape or a polyline shape in which a main body portion extends along the second direction Y, and the sensing signal line 95 is connected to the thirty-second connection electrode 82 through the sixty-second via hole V62. Since the thirty-second connection electrode 82 is connected to the thirteenth connection electrode 63 through a via hole, and the thirteenth connection electrode 63 is connected to the second region of the eighth active layer through a via hole, a connection of the sensing signal line 95 to the second electrode of the eighth transistor T8 is achieved.

In an exemplary implementation, data signal lines 91, first power supply lines 92, and anode connection electrodes 93 of adjacent unit columns may be mirror symmetrical with respect to a centerline.

In an exemplary implementation, the sensing signal line 95 may be led to a bonding region or a bezel region.

(13) A pattern of a third planarization layer is formed. In an exemplary implementation, forming the pattern of the third planarization layer may include: coating a third planarization thin film on the base substrate on which the aforementioned patterns are formed, patterning the third planarization thin film through a patterning process to form a third planarization layer covering the pattern of the sixth conductive layer, wherein the third planarization layer is provided with an anode via hole, an orthographic projection of the anode via hole on the base substrate is within a range of an orthographic projection of the anode connection electrode 93 on the base substrate, the anode via hole exposes a surface of the anode connection electrode 93, and the anode via hole is configured such that an anode to be formed subsequently is connected with the anode connection electrode 93 through the anode via hole.

So far, the driving structure layer has been prepared on the base substrate. In a plane parallel to the display substrate, the driving structure layer may include a plurality of circuit units, each circuit unit may include a pixel driving circuit, a sensing circuit and a photosensitive device, a first scan signal line, a second scan signal line, a third scan signal line, a light emitting signal line, a first initial signal line, a second initial signal line, a first power supply line and a data signal line which are connected to the pixel driving circuit, and a sensing power supply line and a sensing signal line which are connected to the sensing circuit and the photosensitive device. In a plane perpendicular to the display substrate, the driving structure layer may include a first insulation layer, a first semiconductor layer, a second insulation layer, a first conductive layer, a third insulation layer, a second conductive layer, a fourth insulation layer, a second semiconductor layer, a fifth insulation layer, a third conductive layer, a sixth insulation layer, a fourth conductive layer, a first planarization layer, a fifth conductive layer, a second planarization layer, a sixth conductive layer and a third planarization layer which are disposed sequentially on the base substrate. The first semiconductor layer may at least include a first transistor, active layers of a third transistor to a seventh transistor, and a photosensitive active layer. The first conductive layer may at least include a first scan signal line, a second scan signal line, a light emitting signal line, and a first electrode plate of the storage capacitor. The second conductive layer may at least include a first initial signal line, a second electrode plate of the storage capacitor, and an eighth bottom gate electrode. The second semiconductor layer may at least include active layers of a second transistor and an eighth transistor. The third conductive layer may at least include a third scan signal line, a second initial signal line, and an eighth top gate electrode. The fourth conductive layer may at least include a plurality of connection electrodes. The fifth conductive layer may at least include a sensing power supply connection line. The sixth conductive layer may at least include a data signal line, a first power supply line, a sensing power supply line, and a sensing signal line.

In an exemplary implementation, the base substrate may be a flexible substrate, or a rigid substrate. The rigid base substrate may include, but is not limited to, one or more of glass and quartz. The flexible base substrate may be made of, but is not limited to, one or more of polyethylene terephthalate, ethylene terephthalate, polyether ether ketone, polystyrene, polycarbonate, polyarylate, polyarylester, polyimide, polyvinyl chloride, polyethylene, and textile fibers. In an exemplary implementation, the flexible base substrate may include a first flexible material layer, a first inorganic material layer, a semiconductor layer, a second flexible material layer, and a second inorganic material layer which are stacked. Materials of the first flexible material layer and the second flexible material layer may be Polyimide (PI), Polyethylene Terephthalate (PET), or a surface-treated polymer soft film, etc., and materials of the first inorganic material layer and the second inorganic material layer may be Silicon Nitride (SiNx), Silicon Oxide (SiOx), or the like, for improving water and oxygen resistance of the base substrate. The first inorganic material layer and the second inorganic material layer may also be referred to as barrier layers, and a material of the semiconductor layer may be amorphous silicon (a-si).

In an exemplary implementation, the first conductive layer, the second conductive layer, the third conductive layer, the fourth conductive layer, the fifth conductive layer, and the sixth conductive layer may be made of a metal material, such as any one or more of Argentum (Ag), Copper (Cu), Aluminum (Al), and Molybdenum (Mo), or an alloy material of the above metals, such as an Aluminum Neodymium alloy (AlNd) or a Molybdenum Niobium alloy (MoNb), and may be of a single-layer structure or a multi-layer composite structure, such as Mo/Cu/Mo. The first insulation layer, the second insulation layer, the third insulation layer, the fourth insulation layer, the fifth insulation layer, and the sixth insulation layer may be made of any one or more of Silicon Oxide (SiOx), Silicon Nitride (SiNx), and Silicon OxyNitride (SiON), and may be a single layer, multiple layers, or a composite layer. The first planarization layer, the second planarization layer, and the third planarization layer may be made of an organic material, such as a resin.

In an exemplary implementation, the pixel driving circuits in two adjacent circuit units in a unit row may be substantially mirror symmetrical with respect to the centerline. For example, the pixel driving circuits of the n-th unit column and the pixel driving circuits of the (n+1)-th unit column may be mirror symmetrical with respect to the centerline.

In an exemplary implementation, after the driving structure layer has been prepared, a light emitting structure layer is first prepared on the driving structure layer, and then an encapsulation structure layer is prepared on the light emitting structure layer, which will not be repeated here.

In an exemplary implementation, the sensing circuit and the photosensitive device may be disposed in a portion of the circuit units to achieve the in-screen fingerprint function, or the sensing circuit and the photosensitive device may be disposed in all the circuit units to achieve the full-screen fingerprint function, which is not limited in the present disclosure.

An exemplary embodiment of the present disclosure provides a display substrate provided with an LTPO circuit compatible with a fingerprint sensor function. By providing a pixel driving circuit, a sensing circuit, and a photosensitive device in the circuit unit, a full-screen fingerprint function may be achieved. The display substrate of the present disclosure shares a light emitting signal line through a pixel driving circuit and a sensing circuit, so that the high-level time of the light emitting signal line is stable, the acquisition time is not overlapped, the duration of low-gray-scale display is longer, and the signal acquisition is more sufficient, which may effectively meet the driving requirements of the light sensor, achieve the row-by-row scan by the light sensor, and achieve the full-screen fingerprint function.

In the present disclosure, the sensing circuit and the photosensitive device are provided in the circuit unit, so that pitches between the fingerprint sensor formed by the sensing circuit and the photosensitive device and the pixel driving circuit are the same, and the fingerprint sensing accuracy is high. Since a scan width of the gate driving circuit outputting the light emitting signal is adjustable, the fingerprint sampling time and period may be flexibly adjusted, effectively improving the sampling accuracy.

In the present disclosure, the pixel driving circuits are made to be mirror symmetrical, and the sensing circuit and the photosensitive device are provided between adjacent unit columns, thereby effectively utilizing the layout space. In the present disclosure, the light emitting connection electrode is arranged to be connected to the light emitting signal line, so that it is achieved that the light emitting signal line controls the eighth transistor to be turned on and off.

In the present disclosure, a sensing power supply line with a network communication structure is formed on the display substrate, which may not only minimize a resistance of the sensing power supply line, but also reduce a voltage drop of the photosensitive power supply signal, effectively improving the uniformity of the photosensitive power supply signal in the display substrate, and effectively improving the photosensitive uniformity of the photosensitive device.

In the present disclosure, a network communication structure for transmitting the first initial signal and a network communication structure for transmitting the second initial signal are formed on the display substrate, so that a resistance of the initial signal line may be minimized, and a voltage drop of the initial signal is reduced, effectively improving the uniformity of the initial signal in the display substrate, effectively improving display uniformity, and improving display attribute and display quality.

In the present disclosure, a shielding electrode is provided. On the one hand, the shielding electrode may block the light emitted from the light emitting device and the reflected light of the film layer from irradiating oxide transistors, and prevent the characteristic drift of the oxide transistor due to the illumination, improving the electrical characteristics of the oxide transistor, and on the other hand, the shielding electrode may effectively shield the influence of data voltage jumps and other signals on the first node N1 in the pixel driving circuit, and effectively avoiding the worsening of crosstalk.

The preparation process in the present disclosure may be compatible well with an existing manufacturing process, is simple in process implementation, is easy to implement, and has a high production efficiency, a low production cost, and a high yield.

The structure shown and mentioned above in the present disclosure and the manufacturing process therefor are merely an exemplary description. In an exemplary implementation, the corresponding structures may be altered and the patterning processes may be added or reduced according to actual needs. For example, the first transistors T1, the third transistors T3 to the seventh transistors T7 may be arranged to be oxide transistors, and the second transistors T2 and the eighth transistors T8 may be arranged to be polysilicon transistors. As another example, the first transistors T1 to the seventh transistors T7 may be arranged to be polysilicon transistors, and the eighth transistor T8 may be arranged to be oxide transistors. For another example, the pixel driving circuit and the sensing circuit may share a first scan signal line, a second scan signal line or a third scan signal line, which is not limited in the present disclosure here.

In an exemplary implementation, the display substrate of the present disclosure may be applied to another display apparatus having a pixel driving circuit, such as quantum dot display, which is not limited in the present disclosure.

The present disclosure also provides a driving method for a display substrate, for driving the display substrate according to the aforementioned embodiments. In an exemplary implementation, the display substrate includes a plurality of circuit units, and at least one circuit unit includes a pixel driving circuit, a sensing circuit and a photosensitive device. The pixel driving circuit at least includes a driving transistor and at least one light emitting control transistor, wherein a first end of the light emitting control transistor is connected to a first power supply line, a second end of the light emitting control transistor is connected to a first end of the driving transistor, or the first end of the light emitting control transistor is connected to a second end of the driving transistor, and the second end of the light emitting control transistor is connected to a light emitting device; the sensing circuit at least includes a sensing control transistor, wherein a first end of the sensing control transistor is connected with the photosensitive device, a second end of the sensing control transistor is connected to a sensing signal line, and the light emitting control transistor and the sensing control transistor are different types of transistors; and in at least one circuit unit, the light emitting control transistor and the sensing control transistor are connected to the same light emitting signal line, the light emitting signal line is configured to provide a light emitting control signal to the pixel driving circuit. The driving method may include following acts.

At act 1, in a first sensing period, the light emitting signal line controls the sensing circuit to generate a photosensitive current.

At act 2, in a second sensing period, the light emitting signal line controls the pixel driving circuit to output a driving current.

In an exemplary implementation, act 1 may include: in the first sensing period, the light emitting signal line outputs a first signal, so that the light emitting control transistor is turned off, the sensing control transistor is turned on, and the sensing circuit generates a photosensitive current.

In an exemplary implementation, in the first sensing period, the pixel driving circuit performs reset and data writing.

In an exemplary implementation, step 2 may include: in the second sensing period, the light emitting signal line outputs a second signal, so that the sensing control transistor is turned off, the light emitting control transistor is turned on, and the pixel driving circuit outputs a driving current.

In an exemplary implementation, the first signal may be a high-level signal and the second signal may be a low-level signal.

The present disclosure also provides a preparation method for a display substrate, for preparing the display substrate according to the foregoing embodiments. In an exemplary implementation, the display substrate includes a plurality of circuit units, and the preparation method may include:
forming a pixel driving circuit, a sensing circuit and a photosensitive device in at least one circuit unit; the pixel driving circuit at least includes a driving transistor and at least one light emitting control transistor, wherein a first end of the light emitting control transistor is connected to a first power supply line, a second end of the light emitting control transistor is connected to a first end of the driving transistor, or the first end of the light emitting control transistor is connected to a second end of the driving transistor, and the second end of the light emitting control transistor is connected to a light emitting device; the sensing circuit at least includes a sensing control transistor, wherein a first end of the sensing control transistor is connected with the photosensitive device, a second end of the sensing control transistor is connected to a sensing signal line, and the light emitting control transistor and the sensing control transistor are different types of transistors; and in at least one circuit unit, the light emitting control transistor and the sensing control transistor are connected to the same light emitting signal line, the light emitting signal line is configured to provide a light emitting control signal to the pixel driving circuit.

The present disclosure also provides a display apparatus which includes the aforementioned display substrate. The display apparatus may be any product or component with a display function, such as a mobile phone, a tablet computer, a television, a display, a laptop computer, a digital photo frame, or a navigator, which is not limited in the embodiments of the present invention.

Although implementations disclosed in the present disclosure are as above, it should be noted that the above implementations are exemplary only rather than restrictive. Therefore, the present disclosure is not limited to what is specifically shown and described herein. Various modifications, substitutions or omissions may be made in forms and details of implementations without departing from the scope of the present disclosure.

1. A display substrate, comprising a plurality of circuit units, wherein
at least one circuit unit comprises a pixel driving circuit, a sensing circuit and a photosensitive device, the pixel driving circuit at least comprises a driving transistor and at least one light emitting control transistor;
a first end of the light emitting control transistor is connected to a first power supply line, and a second end of the light emitting control transistor is connected to a first end of the driving transistor; or the first end of the light emitting control transistor is connected to a second end of the driving transistor, and the second end of the light emitting control transistor is connected to a light emitting device;
the sensing circuit at least comprises a sensing control transistor, a first end of the sensing control transistor is connected with the photosensitive device, a second end of the sensing control transistor is connected to a sensing signal line, and the light emitting control transistor and the sensing control transistor are different types of transistors; and
in at least one circuit unit, the light emitting control transistor and the sensing control transistor are connected to a same light emitting signal line, and the light emitting signal line is configured to provide a light emitting control signal to the pixel driving circuit.

2. The display substrate according to claim 1, wherein
the light emitting control transistor is a polysilicon transistor and the sensing control transistor is an oxide transistor; or
the light emitting control transistor is an oxide transistor, and the sensing control transistor is a polysilicon transistor.

3. The display substrate according to claim 1, wherein
the light emitting control transistor at least comprises a light emitting control gate electrode,
the sensing control transistor at least comprises a sensing control gate electrode,
the light emitting control gate electrode is directly connected to the light emitting signal line, and
the sensing control gate electrode is connected to the light emitting signal line through a light emitting connection electrode.

4. The display substrate according to claim 3, wherein
in a direction perpendicular to the display substrate, the display substrate comprises a plurality of conductive layers,
the light emitting control gate electrode and the light emitting signal line are disposed in the same conductive layer,
the sensing control gate electrode and the light emitting signal line are disposed in different conductive layers, and
the light emitting connection electrode and the sensing control gate electrode are disposed in different conductive layers.

5. The display substrate according to claim 4, wherein
the plurality of conductive layers at least comprise a first conductive layer, a second conductive layer, a third conductive layer and a fourth conductive layer disposed sequentially;
the light emitting signal line and the light emitting control gate electrode are disposed in the first conductive layer and are of an integral structure connected to each other;
the sensing control gate electrodes are respectively disposed in the second conductive layer and the third conductive layer; and
the light emitting connection electrode is disposed in the fourth conductive layer, and the light emitting connection electrode is respectively connected with the light emitting signal line and the sensing control gate electrode through a via hole.

6. The display substrate according to claim 5, wherein
the sensing control gate electrode comprises a bottom gate electrode and a top gate electrode;
the bottom gate electrode is disposed in the second conductive layer, the top gate electrode is disposed in the third conductive layer, and the light emitting connection electrode is respectively connected to the bottom gate electrode and the top gate electrode through a via hole.

7. The display substrate according to claim 1, wherein
the photosensitive device comprises at least a photosensitive first electrode, a photosensitive second electrode, and a photosensitive layer disposed between the photosensitive first electrode and the photosensitive second electrode,
the photosensitive first electrode is connected to a sensing power supply line, and
the photosensitive second electrode is connected to a first electrode of the sensing control transistor.

8. The display substrate according to claim 7, wherein
the sensing control transistor at least comprises a sensing active layer;
in a direction perpendicular to the display substrate, the display substrate at least comprises a first semiconductor layer disposed on a base substrate and a second semiconductor layer disposed on a side of the first semiconductor layer away from the base substrate; and
the photosensitive first electrode, the photosensitive second electrode and the photosensitive layer are disposed in the first semiconductor layer, and the sensing active layer is disposed in the second semiconductor layer.

9. The display substrate according to claim 8, wherein the photosensitive first electrode and the photosensitive second electrode are formed by performing a conductorization treatment on the first semiconductor layer, and the photosensitive layer is formed by doping the first semiconductor layer.

10. The display substrate according to claim 8, wherein the at least one circuit unit further comprises an eleventh connection electrode and a thirty-first connection electrode, and the photosensitive first electrode is connected to the sensing power supply line through the eleventh connection electrode and the thirty-first connection electrode.

11. The display substrate according to claim 10, wherein
in a direction perpendicular to the display substrate, the display substrate comprises a plurality of conductive layers, and the eleventh connection electrode, the thirty-first connection electrode and the sensing power supply line are disposed in different conductive layers;
the eleventh connection electrode is connected to the photosensitive first electrode through a via hole, the thirty-first connection electrode is connected to the eleventh connection electrode through a via hole, and the sensing power supply line is connected to the thirty-first connection electrode through a via hole.

12. The display substrate according to claim 8, wherein the at least one circuit unit further comprises a twelfth connection electrode, and the photosensitive second electrode is connected to a first region of the sensing active layer through the twelfth connection electrode.

13. The display substrate according to claim 12, wherein the twelfth connection electrode is disposed on a side of the sensing active layer away from the base substrate, the twelfth connection electrode is connected to the photosensitive second electrode through a via hole, and the twelfth connection electrode is connected to the first region of the sensing active layer through another via hole.

14. The display substrate according to claim 8, wherein the at least one circuit unit further comprises a thirteenth connection electrode and a thirty-second connection electrode, a second region of the sensing active layer is connected to the sensing signal line through the thirteenth connection electrode and the thirty-second connection electrode; wherein
in a direction perpendicular to the display substrate, the display substrate comprises a plurality of conductive layers, and the thirteenth connection electrode, the thirty-second connection electrode and the sensing signal line are disposed in different conductive layers;
the thirteenth connection electrode is connected to the second region of the sensing active layer through a via hole, the thirty-second connection electrode is connected to the thirteenth connection electrode through a via hole, and the sensing signal line is connected to the thirty-second connection electrode through a via hole.

15. (canceled)

16. The display substrate according to claim 7, wherein
a shape of the sensing power supply line is a straight line shape or a polyline shape in which a main body portion extends along a second direction; and
at least one circuit unit further comprises a sensing power supply connection line, a shape of the sensing power supply connection line is a straight line shape or a polyline shape in which a main body portion extends along a first direction, and the sensing power supply line is connected with the sensing power supply connection line to form a network communication structure.

17. A display apparatus, comprising a display substrate according to claim 1.

18. A driving method of a display substrate, which comprises a plurality of circuit units, and at least one circuit unit comprises a pixel driving circuit, a sensing circuit and a photosensitive device; wherein
the pixel driving circuit at least comprises a driving transistor and at least one light emitting control transistor; wherein
a first end of the light emitting control transistor is connected to a first power supply line, and a second end of the light emitting control transistor is connected to a first end of the driving transistor; or
the first end of the light emitting control transistor is connected to a second end of the driving transistor, and the second end of the light emitting control transistor is connected to a light emitting device;
the sensing circuit at least comprises a sensing control transistor, wherein a first end of the sensing control transistor is connected with the photosensitive device, a second end of the sensing control transistor is connected to a sensing signal line, and the light emitting control transistor and the sensing control transistor are different types of transistors;
in at least one circuit unit, the light emitting control transistor and the sensing control transistor are connected to a same light emitting signal line, the light emitting signal line is configured to provide a light emitting control signal to the pixel driving circuit; and
the driving method comprises following periods:
in a first sensing period, controlling, by the light emitting signal line, the sensing circuit to generate a photosensitive current; and
in a second sensing period, controlling, by the light emitting signal line, the pixel driving circuit to output a driving current.

19. The driving method according to claim 18, wherein the controlling, by the light emitting signal line, the sensing circuit to generate a photosensitive current comprises:
outputting a first signal by the light emitting signal line,
turning off the light emitting control transistor,
turning on the sensing control transistor, and
generating a photosensitive current by the sensing circuit.

20. The driving method according to claim 18, wherein the controlling, by the light emitting signal line, the pixel driving circuit to output a driving current comprises:
outputting a second signal by the light emitting signal line,
turning off the sensing control transistor,
turning on the light emitting control transistor, and
outputting a driving current by the pixel driving circuit.

21. A preparation method for a display substrate comprising a plurality of circuit units, the method comprising:
forming a pixel driving circuit, a sensing circuit and a photosensitive device in at least one circuit unit; wherein
the pixel driving circuit at least comprises a driving transistor and at least one light emitting control transistor, wherein
a first end of the light emitting control transistor is connected to a first power supply line, and a second end of the light emitting control transistor is connected to a first end of the driving transistor; or
the first end of the light emitting control transistor is connected to a second end of the driving transistor, and the second end of the light emitting control transistor is connected to a light emitting device;
the sensing circuit at least comprises a sensing control transistor, wherein a first end of the sensing control transistor is connected with the photosensitive device, a second end of the sensing control transistor is connected to a sensing signal line, and the light emitting control transistor and the sensing control transistor are different types of transistors; and
in at least one circuit unit, the light emitting control transistor and the sensing control transistor are connected to the same light emitting signal line, the light emitting signal line is configured to provide a light emitting control signal to the pixel driving circuit.
